(19) United States
(12) Patent Application Publication
(10) Pub. No.: US 2011/0062430 A1
(43) Pub. Date: Mar. 17, 2011

(54) BLUE LIGHT EMITTING NANOMATERIALS AND SYNTHESIS THEREOF

(76) Inventors: Franciscus Cornelis Jacobus Maria van Veggel, Victoria, (CA); Mingqian Tan, Cleveland, OH (US); Venkataramanan Mahalingam, Tamil Natu (IN); Vasanthakumaran Sudarsan, Mumbai (IN)

(21) Appl. No.: 12/994,273

(22) PCT Filed: Jun. 1, 2009
(86) PCT No.: PCT/US09/45850

§ 371 Date: Nov. 23, 2010

Related U.S. Application Data
(60) Provisional application No. 61/057,982, filed on Jun. 2, 2008.

(51) Int. Cl. H01L 51/54; H01L 33/32; C01B 35/00; C01B 21/00; C09K 11/02; C09K 11/62; C01F 17/00; B82Y 40/00

(52) U.S. Cl. 257/40; 438/45; 423/276; 423/351; 252/301.36; 252/301.4 F; 423/263; 977/840; 257/E33.03; 257/E51.026

(57) ABSTRACT

Methods for the production of a blue light emitting nanomaterial are provided comprising nitriding Group 13 metals to produce nitrided Group 13 metals and doping the nitrided Group 13 metals with a dopant, particularly an M²⁺ dopant, such as Mg²⁺ or Zn²⁺, to produce doped nanoparticles. Blue light emitting nanocomposites on other materials, such as SiO₂ or TiO₂, are also provided. Blue light emitting nanomaterials and nanocomposites also can be coupled to photonic crystals. Nanocrystal-based electroluminescence device are also disclosed.

### CROSS REFERENCE TO RELATED APPLICATIONS

This is the U.S. National Stage of International Application No. PCT/US2009/045850, filed Jun. 1, 2009, which was published in English under PCT Article 21(2), which in turn claims the benefit of U.S. provisional application No. 61/057,982, filed Jun. 2, 2008. The provisional application is incorporated herein in its entirety.

### FIELD

The present technology relates to blue light emitting nanoparticles, and their use in electroluminescent devices. The technology more specifically relates to blue light emitting nanomaterials, the synthesis and use thereof.

### BACKGROUND

Blue is one of the primary colors used in white light and hence materials that are sources of blue light are technologically important. There is interest in using blue and ultraviolet light emitting diodes (UV LEDs) as light sources, as well as blue and white organic molecule light-emitting diode (OLEDs). Unfortunately known devices have low efficiencies and poor stability.

Blue light emission has been observed from Mg²⁺-, Tm³⁺- and As-doped GaN films and nanowires. For example, Lee and Steckl (D. S. Lee, A. J. Steckl, Appl. Phys. Lett. 2003, 83, 2094.) observed enhanced blue emission from Tm³⁺-doped AlGaN electroluminescent devices (EL). As GaN is a very robust material, there was hope that GaN film-based devices would provide the characteristics needed for LEDs. However, these devices cannot be conveniently fabricated, and therefore, fabrication costs are very high.

There are a few reports of blue emission from GaN-based nanomaterials. For example, thermal decomposition of an amido precursor [Ga₂(NMe₂)₆] in NH₃ resulted in the formation of a polymeric intermediate, which on reaction with NH₃ resulted in the GaN nanoparticles. Recently, van Patten et al. (G. Q. Pan, M. E. Kordesch, P. G. Van Patten, Chem. Mater. 2006, 18, 3915.) discovered that the same precursor can be used to produce GaN nanocrystals without using NH₃.

The same group reported a room-temperature synthesis of GaN from Li₃N and GaCl₃ that emits at 320 nm, which shifted to 365 nm upon annealing at 310° C. Solvothermal decomposition of GaCl₃ and NaN₃ mixture and in situ thermal decomposition of cyclotrigallazane incorporated into a polymer results in the formation of GaN nanoparticles which exhibited blue emission near 426 and 475 nm, respectively. However, the origin of the blue emission is mainly attributed to the presence of impurity or defect levels, which was not desirable, as it is difficult to reproduceably produce the desired result. Moreover, many of the GaN nanoparticles synthesis involve using azides and other organometallic reagents as precursors for gallium and nitrogen. These organometallic precursors and azides are highly explosive, very toxic, and extremely sensitive to air, which requires that reactions be performed with extreme care in a glove box.

Recently, InN nanomaterials have attracted increasing attention because of their potential applications in building optoelectronic nanodevices. Indium nitride (InN) is an important semiconductor of the group-13 (also known as group-III) nitrides with high electron mobility, low band gap, and low toxicity. However, it remains relatively less studied compared to other group-13 nitrides due to its low thermal stability, low dissociation temperature, and high equilibrium vapor pressure. Generally, InN thin films are made through high-temperature processes, such as reactive magnetron sputtering, metalorganic vapor phase epitaxy (MOVPE), and molecular-beam epitaxy (MBE). The development of InN-based nanomaterials enables the possibility of separation between the high-temperature synthesis and the formation of the emission layer.

To date, there have been several efforts to prepare nano-sized InN semiconductors; however, investigations on blue electroluminescence (EL) from InN-based nanoparticles have not been reported.

### SUMMARY

The present technology provides a number of approaches for the production of blue light emitting nanoparticles, nanomaterials, nanocomposites and electroluminescent devices. The products of the methods have high efficiencies and good stability. The nanocomposites and nanomaterials emit blue light with a maximum at about 420 nm to about 500 nm.

The foregoing and other objects, features, and advantages of the invention will become more apparent from the following detailed description, which proceeds with reference to the accompanying figures.

### BRIEF DESCRIPTION OF THE DRAWINGS

FIG. 1 is a schematic providing one embodiment of a method for making Mg²⁺-doped GaN nanoparticles in an inert matrix.

FIG. 2 is a normalized emission spectra of Mg²⁺-doped GaN nanoparticles before (dashed trace) and after (solid trace) removal of the Eu³⁻-doped La₂O₃ matrix.

FIG. 3 provides experimental (dotted trace) and calculated (solid trace) X-ray diffraction patterns of Mg²⁺-doped GaN nanoparticles after removal of the La₂O₃ inert matrix and MgO, where the small peaks at left, from left to right, were cristobalite, most likely from the quartz tube in the furnace, and some remaining La₂O₃, respectively.

FIG. 4 provides electroluminescence (EL) spectra of GaN:Mg nanocrystals-based EL device with a configuration of ITO/PEDOT:PSS/GaN:Mg/Ca/Al.

FIG. 5 provides a comparison of photoluminescence (PL) and EL spectra obtained from an ITO/PEDOT:PSS/GaN:Mg/Ca/Al device. EL spectrum of a control device, ITO/PEDOT:PSS/Ca/Al, is shown for comparison, where the applied voltages for PEDOT:PSS//GaN:Mg and PEDOT:PSS were 14 V and 8 V, respectively.

FIG. 6 are PL spectra of Zn-doped (solid trace) and undoped (dotted trace) GaN nanoparticles.

FIG. 7 provides PL spectra of GaN nanoparticles incorporated with different amounts of (A) Mg²⁺, and (B) Zn²⁺ ions.

FIG. 8 is a TEM image of silica-coated, Mg²⁺-doped GaN nanoparticles.

FIG. 9 is a schematic representation of one disclosed embodiment of a method for making Eu²⁺-doped GaN/SiO₂ nanocomposites.

FIG. 10 provides TEM images of the (a) Eu³⁺-doped Ga₂O₃/SiO₂ and (b) Eu²⁻-doped GaN/SiO₂ nanocomposites, where the arrows indicate the attachment of small GaN nanoparticles onto the silica surface, and with the inset showing the enlarged view of a single Eu²⁺-doped GaN/SiO₂ nanocomposite for clarity.

FIG. 11 are PL emission spectra collected from (a) Eu²⁺-doped GaN/SiO₂ nanocomposites, (b) Eu³⁺-doped Ga₂O₃@SiO₂ after heating in air at 900° C., and (c) bare SiO₂ nanoparticles after heating at 900° C. in NH₃ (λₑₓ=285 nm), where the insert is an the excitation spectrum collected from the nanocomposites (λₑₘ=450 nm).

FIG. 12 is an EPR spectrum of Eu²⁺-doped GaN/SiO₂ nanocomposites, recorded at 135 K in the X-band (9.44 GHz).

FIG. 13 provides (a) EL spectra collected from an ITO//Eu²⁺-doped GaN/SiO₂//Ca//Al EL device and from two control devices such as ITO//GaN/SiO₂//Ca//Al and ITO//Eu³⁺-doped Ga₂O₃@SiO₂//Ca//Al, with the PL spectrum of Eu²⁺-doped GaN/SiO₂ being shown, along with (b) Current (A)-voltage (V) characteristics from an ITO//Eu²⁺-doped GaN/SiO₂//Ca//Al EL device.

FIG. 14 is (a) a TEM image, and (b) a digital photograph collected from the PMMA coated Eu²⁺-doped GaN/SiO₂ nanocomposites, with an enlarged TEM image of one polymer-coated nanocomposite being shown in the inset.

FIG. 15 is a TEM image of InN@SiO₂ nanomaterial.

FIG. 16 provides emission spectrum of (A) InN@SiO₂ nanomaterial, (B) bare silica particle after nitridation, (C) In₂O₃@SiO₂ heat treated in Argon, and (D) In₂O₃ and SiO₂ mixed prior to nitridation, where the inset shows the excitation spectrum collected from InN@SiO₂ nanomaterial, and where spectra B, C, and D were multiplied by 3 for clarity.

FIG. 17 provides (a) absorption (dotted) and photoluminescence (solid) spectra of InN@SiO₂ nanomaterials, where photoluminescence spectra were measured with a 450 W Xe arc lamp excitation in KBr pellet, and (b) a TEM image and a schematic representation (insert) of InN@SiO₂ nanomaterials.

FIG. 18 provides PL and EL spectra of InN@SiO₂ nanoparticles, with the applied voltages for EL being (a) 14 V, (b) 10 V, and (c) 9 V, respectively, and where (d) EL of In₂O₃/SiO₂ control nanoparticles at a driven voltage of 18 V. (Insert) CIE color coordinates of the resulting blue EL emission and a photo taken from the working device.

FIG. 19 are XRD patterns of intermediate Mg²⁺-doped products, where the relative Mg/Ga percentage concentration measured with EDX is indicated beside each pattern, and the solid sticks indicate the reference pattern of Ga₂MgO₄ and dashed sticks the one of Ga₂O₃.

FIG. 20 are XRD patterns of intermediate Zn²⁺-doped products, where the relative Zn/Ga percentage concentration measured with EDX is indicated beside each pattern, and the solid sticks indicate the reference pattern of Ga₂ZnO₄ and dashed sticks are for Ga₂O₃.

FIG. 21 are XRD patterns of the final Mg²⁺-doped products, where the relative Mg/Ga percentage concentration of the initial mixture is indicated beside each pattern, the solid sticks indicate the reference pattern of GaN, and the dashed sticks the for MgO.

FIG. 22 are XRD patterns of the final Zn²⁺-doped products, where the relative Zn/Ga percentage concentration of the initial mixture is indicated beside each pattern, and where the solid sticks indicate the reference pattern of GaN and dashed sticks are for ZnO.

FIG. 23 is a TEM image of 2.9% doped Zn:GaN.

FIG. 24 are PL spectra of 4.3% Zn²⁺ doped (solid trace) and undoped (dotted trace) GaN nanoparticles.

FIG. 25 are PL spectra of 24.7% Mg²⁺-(dotted) and 2.6% Zn²⁺-doped (solid) GaN nanoparticles, where the inset shows the Gaussian fittings of the PL from Zn²⁺-doped GaN nanoparticles

FIG. 26 are PL spectra of GaN nanoparticles incorporated with different nominal amounts of (A) Mg²⁺ and (B) Zn²⁻ ions, where the order in the legend box is inverted because it is consistent with the initial concentrations.

FIG. 27 are Raman spectra of 24.7% Mg²⁺-, 2.6% Zn²⁺-doped and undoped GaN nanoparticles.

FIG. 28 are digital images of direct and inverse opals: a) 10× magnification of a direct opal made of PBs; b) 40× magnification of Eu²⁺-doped silica inverse opal in transmission mode; c) 40× magnification of Eu²⁺-doped silica inverse opal in reflection mode; and d) 100× magnification of FIG. 19c.

FIG. 29 are transmission spectra of the direct and inverse opals made of 400 nm PBs, with the assignment of the stop bands based on the planes responsible for them being indicated.

FIG. 30 are SEM images of the Eu²⁺-doped inverse opal, where FIG. 30a shows the surface with a 90° angle of incidence, and FIGS. 30b, c and d are at a 60° angle and show the thickness of the inverse opal, with the scale bar measuring 2, 20, 3, and 2 μm in FIGS. 30a, b, c and d, respectively.

FIG. 31 are a) transmission spectra, b) emission spectra of sample (solid line) and references (dotted line), with the reference sizes of the initial PBs used for the preparation of the samples being indicated on the transmission spectra.

FIG. 32 are transmission spectra, where a) is Eu²⁺ lifetimes at different wavelengths, λex: 355 nm, and b) is the Ratio between the reference and the sample, with the transmission spectrum of the sample being superimposed.

FIG. 33 is an Electron Paramagnetic Resonance spectra of a blue light emitting nanoparticle comprising Eu²⁺.

FIG. 34 are PL spectra of 24.7% Mg²⁺-(dotted) and 2.6% Zn²⁺-doped (solid) GaN nanoparticles, where the inset shows the Gaussian fittings of the PL from Zn²⁺-doped GaN nanoparticles.

FIG. 35 are PL spectra of GaN nanoparticles incorporated with different nominal amounts of (A) Mg²⁺ and (B) Zn²⁻ ions, and where the order in the legend box is inverted because it is consistent with the initial concentrations.

### DETAILED DESCRIPTION

### I. Definitions

The following definitions are provided solely to aid the reader. These definitions should not be construed to provide a definition that is narrower in scope than would be apparent to a person of ordinary skill in the art.

Nanomaterial—Any nanoparticle, nanocrystal, or nanocomposite. In general a nanomaterial is a material with at least one length scale below 100 nm.

Nanoparticles—Includes nanoparticles and nanocrystals. Often nanoparticle and nanocrystal are used interchangeable, but a nanocrystal has to be crystalline, a nanoparticle not necessarily crystalline.

Nanocrystal—A nanoparticle that is necessarily crystalline.

Nanocomposite—A composition that has at least one nanomaterial, nanoparticle or nanocrystal in it.

Controllable defects—Defects in a nanoparticle that can be controlled by the amount of M²⁺ doping, such as Mg²⁺ and Zn²⁺ doping, of the nanoparticles. These differ from defects that arise in thin layers. The latter tend to be uncontrollable.

@—indicates that the nanomaterial is grown on an interface material, such as SiO₂ or TiO₂.

### II. Blue Light Emitting Nanoparticles

The present technology concerns blue-light emitting doped nanomaterials, and a method for making such as nanomaterials. For example, doped GaN nanoparticles have been made that exhibit blue emission around 410 nm. The nanomaterials comprise Group 13 (M¹³) elements, particularly gallium and indium. The Group 13 elements are doped with charged metal ions, particularly metal ions having a 2+ charge (M²⁺). The nanomaterials are exemplified herein by GaN and InN nanoparticles, and the charged metal ion dopants are exemplified by Cu²⁺, Eu²⁻, Mg²⁺, Mn²⁺, Ni²⁺ and Zn²⁺ ions, with Eu²⁺, Mg²⁺, and Zn²⁺ being most commonly used for disclosed embodiments. Disclosed nanomaterials are doped with an effective amount of a dopant, which may be from greater than 0 atom percent to at least 10 atom percent, and more typically is from about 1 atom percent to about 5 atom percent.

Certain disclosed nanomaterials satisfy a formula

M¹³N₁₋ₓ-M²⁺

with 1−x being close to one, and where M¹³ and M²⁺ are as stated above. If M²⁺ replaces the M¹³ element, such as Ga³⁺, then nitrogen vacancies may compensate for the charge difference of the cation. This is not the only way charge neutrality can be achieved, and so it stating a more precise numerical value for x is difficult.

Disclosed embodiments also may include an interface material, such as SiO₂ and TiO₂. These materials often satisfy the general formula

M¹³N₁₊ₓ—(SiO_{2-y} or TiO_{2-y})

where 1+x is slightly greater than one and 2−y is slightly smaller than 2. This result is based on elemental analysis, which shows that there is more nitrogen than is strictly needed for InN, and not enough oxygen for SiO₂.

Doped materials having an interface typically have a formula

M¹³N₁₊ₓ:M²⁺@(SiO_{2-y} or TiO_{2-y})

where 1+x is slightly greater than one and 2−y is slightly smaller than 2. Again, this result is based on elemental analysis, which shows that there is more nitrogen than is strictly needed for M¹³N, and not enough oxygen for SiO₂.

Disclosed embodiments concern nanoparticles that were prepared by the nitridation of suitable substrate materials, such as nitridation of Mg²⁺- and Zn²⁺-doped gallium oxide nanoparticles in an ammonia atmosphere, at an effective temperature, such as greater than 500° C., and more typically greater than 750° C., such as from about 950° C. to 1,200° C., depending on the melting point of the dopant. The high temperature employed in certain preparations led to the sintering of GaN nanoparticles, thus hindering the post chemical treatment to improve their processability in organic medium. To circumvent this problem, a method has been developed in which the precursor 2+-doped Group 13 oxide nanoparticles were first diluted in an inert matrix before the nitridation reaction. This was achieved by mixing the precursor nanoparticles with Eu³⁺-doped La₂O₃ matrix in the ratio 1:10. Eu³⁻ was used as an optical probe to determine if any changes occurred in the matrix during the nitridation step. After the nitridation, the doped GaN nanoparticles were separated from the matrix by dissolving the matrix. For Mg²⁺-doped nanoparticles, some examples formed MgO completely with 10% aqueous HNO₃. The optical properties of the Mg²⁺-doped GaN nanoparticles were not affected by the nitric acid treatment.

Certain disclosed embodiments concern coating nanoparticles with a coating material. The nanoparticles can be coated for a variety of purposes, such as to improve their dispersibility. The coating material typically includes two components. A first component, such as a phosphorus atom, that is useful for binding to the surface of the nanoparticle. A second component, typically an aliphatic organic component, is selected to increase the dispersibility of the nanoparticles. For example, the organic component can be one or more aliphatic chains, as exemplified by alkyl chains having a chain length of up to at least 10 carbon atoms. Particular disclosed embodiments used trioctylphosphine oxide as the coating material.

A hybrid polymer-GaN:Mg structure electroluminescence (EL) device utilizing these GaN:Mg nanocrystals as light-emitting material also has been fabricated. The GaN:Mg nanocrystal-based EL device exhibited a white EL emission from GaN:Mg nanocrystals (NCs).

Bright blue luminescence (˜425 nm) from nanoparticles produced according to the present invention, as exemplified by both Mg²⁺-and Zn²⁺-doped GaN nanoparticles, has been accomplished. The effect of the doping concentrations of these ions on the structural and optical properties was systematically studied using photoluminescence (PL), Raman and X-ray photoelectron spectroscopy (XPS). While the Raman spectroscopic analysis confirmed the distortion of the GaN lattice due to the incorporation of these ions, XPS suggests that the most likely location of the magnesium ions was the gallium lattice. Blue light emission arises from defects, and these defects can be controlled by controlling the amount of Mg²⁺ or Zn²⁺. Finally, a thin shell of silica was coated on the GaN nanoparticles to improve their dispersability.

A magnesium-doped, gallium-nitridenanocrystals-(GaN:Mg NCs)-based electroluminescence (EL) device with a hybrid organic/inorganic structure of indium tin oxide (ITO)/poly(3,4-ethylene dioxythiophene) doped with poly(styrenesulphonic acid) (PEDOT:PSS)/GaN:Mg NCs/Ca/Al has also been fabricated. The conducting polymer, PEDOT:PSS layer, was used to enhance hole injection from the ITO electrode. Current-voltage characteristics of the GaN:Mg nanocrystal-based EL device show a diode-like behavior. White electroluminescence was observed from the device and a voltage-dependent phenomenon of EL emission spectra was found and investigated. A good correlation between the EL and photoluminescence emission peaks suggested that electron-hole recombination indeed occur in the GaN:Mg nanocrystals layer.

Eu²⁺-doped GaN/SiO₂ composite nanomaterials also have been made via a simple solid state reaction. The synthetic strategy was to grow a shell of Eu³⁺-doped Ga₂O₃ on the surface of silica nanoparticles, followed by nitridation with a nitrogen source, such as NH₃. This material exhibited a blue emission when excited in the ultraviolet region. The origin of the blue emission was attributed to the presence of europium ions in the +2 oxidation state, probably at the interface of GaN and silica. This was supported by several control experiments. The nitridation performed in ammonia atmosphere not only assisted the GaN formation over silica but also reduced Eu³⁺ to Eu²⁻. These nanocomposites were dispersible in toluene after coating with a thin layer of polymer, which was advantageous for the fabrication of polymer-based LEDs. The presence of GaN on silica was advantageous in improving the semiconductor property of the materials and potentially makes the growth of p- and n-type doped GaN materials possible. These advantages were lacking for GaN materials coated with silica. The Eu²⁺-doped GaN/SiO₂ nanocomposites were characterized by TEM, EDS, XRD, FT-IR, EPR, and photoluminescence analyses.

Blue photoluminescence (˜450 nm) has also been demonstrated from InN@SiO₂ nanomaterials. The InN@SiO₂ nanomaterials were prepared by a precipitation reaction followed by a solid-state reaction. Various control experiments demonstrated that the interface between the InN and SiO₂ seemed to play an important role in the origin of the blue emission from the InN@SiO₂ nanomaterial. The InN@SiO₂ nanomaterial was characterized using analytical methods such as TEM, XRD, Raman, XPS, and photoluminescence spectroscopy, confirming the existence of InN on SiO₂ with a small excess of nitrogen relative to indium.

### III. Photonic Crystals

### A. Introduction

In the past, the most common way to control the characteristics of the electromagnetic radiation was to choose the appropriate vibronic energy levels structure of the material, which was the source of radiation. Lately, photonic materials are being pursued. Photonic materials are able to modify the radiation by acting on the structure of the photonic levels. Photonic crystals are promising materials from these points of view. They are systems in which the periodic modulation of the dielectric constant over the structure of the material generates a forbidden gap of photonic states, in a similar way as a periodic lattice of atomic potentials determine a forbidden electronic gap in semiconductor crystals. The combination of Bragg scattering from the periodicity of the structure and Mie scattering resonance leads to the complete exclusion of electromagnetic modes over a continuous range of wavelengths. If the periodicity of the system is not perfect or the contrast in the dielectric constant inside the structure is low, instead of a photonic band gap only a reduction of Density of States (DOS) is observed, which is normally called a Stop Band (SB).

The simplest photonic crystals are mono-dimensional: the periodicity of the system and hence the gap occurs just in one direction or at different wavelengths for different directions. They are employed as coatings on lenses or mirrors to modulate the reflectivity, as color changing paints and inks, etc. Two dimensional photonic crystals are used to design optical waveguides, nano-cavities, optical fibres, and as low threshold lasers. Three dimensional photonic crystals are hard to achieve, but they will probably open the door to optical computing. These materials are attracting more and more interest also in the hope that, in the near future, photons will be able to replace electrons as information carriers in integrated microcircuits. Photons present several advantages with respect to electrons: they can travel through dielectric materials much faster, they can carry a larger amount of information, and the energy losses are also reduced because as bosons they are not as strongly interacting as electrons. So far, photonic crystals have mainly been used as a tool to control the propagation of light through the material: drive it along particular directions and stop it along others. The challenge now is to understand what happens at the wavelengths on the sides of the stop bands. There is still some theoretical disputation about this, but the most credited mechanism is that the reduction of the DOS within the SB range is accompanied by an increase of DOS on the sides of the stop band. This redistribution would have determinant consequences for the design of new devices able to purify and intensify the emission at certain wavelengths.

The present technology concerns coupling blue light emitting materials, particularly nanoparticles, with photonic crystals to further tune the emission characteristics of the blue light emitters. For example, this is exemplified by using Eu²⁻ as the responsible emitter in a hybrid material based on GaN in SiO₂, which has an intense and fairly broad emission with the maximum in the blue, but tailing into the green. Such material was shaped into an inverse opal (air voids in silica doped matrix), in which the size of the holes in the different samples was varied between 300 and 540 nm, in order to tune the SB in different positions with respect to the Eu²⁻ emission. Besides the modifications of the lifetime, a decrease of spontaneous emission in the range of the photonic stop band and an increase around the low energy edge of such incomplete gap was observed, in agreement with the modification of the DOS predicted by the theory. This effect is presumed to also occur on the high energy side, but in our sample this is probably obscured by the fact that the emission decreases very steeply.

Constancy in quantum yield (QY) is observed over the whole range of the spontaneous emission. This means that for an emitter placed inside a photonic crystal the reduction of the local density of states not only determines a redistribution of emission along different directions, but also redistribution to different wavelengths. This behavior can be referred to as a “smart filter”: it demotes certain wavelengths and promotes others without wasting intensity, as an ordinary filter would do. A change in color coordinates due to this redistribution has indeed been observed. Such an enhancement of spontaneous emission, especially towards higher energies, allows production of more efficient devices, exploiting radiation at shorter wavelengths.

### B. Theory

In order to describe the behavior of light in a photonic crystal the solutions of Maxwell equations in a periodic dielectric medium should be considered. After simple manipulations they can be rewritten in the form:

$$∇ \times [ \frac{1}{ɛ ( r )} ∇ \times H ( r ) ] = \frac{{ω}^{2}}{{c}^{2}} H ( r ) \qquad Equation 1$$

In which ε(r) is the dielectric function, H(r) the magnetic field of the photon, ω the frequency and c the speed of light. It is possible to demonstrate that the operator on the magnetic field is Hermitian

$$[ \hat{Θ} = ∇ \times \frac{1}{ɛ ( r )} \times ] .$$

Therefore, equation 1 can be seen as an eigenvalue equation and the diagonalization of \hat{Θ} can be performed completely by considering the strength and the symmetry properties of ε(r). In such a way a band structure is spanned with regions of allowed wave-vectors and forbidden gaps. An important difference with respect to the case of electrons in solids is that for photons there is nothing like a Bohr radius. Therefore, the energy of the system is scalable with respect to the size and the dielectric constant, without any modifications on the shape of the spectrum. This treatment can be extended to two and three dimensions to determine the photonic band structure depending on the periodicity of the system. A rough approximation of the wavelength of the SB can be determined considering a modified version of the Bragg's law, combined with Snell's law.

$$λ = \frac{2 Sa}{m \sqrt{{h}^{2} + {k}^{2} + {l}^{2}}} [ φ {n}_{1} + ( 1 - φ ) {n}_{2} ] \qquad Equation 2$$

Where λ is the wavelength, S is a shrinkage factor, which takes into accounts the eventual shrinkage that a structure undergoes during its formation (vide infra), a is the cell's parameter, m is the order of Bragg's diffraction, n₁ and n₂ are the refractive indexes of the materials constituting the structure, and φ is the volume fraction of one of them, the other being the complementary (1−φ). In the case of direct or inverse opals, where the periodicity of the system is distorted by defects, SBs are relatively broad and equation 2 is a good prediction of the SB position.

If an emitter is inserted into a photonic crystal, its spectroscopic properties are modified by the presence of the photonic band gap. The best way to describe this is considering Fermi's golden rule:

W=2π|V_{fi}|²ρ(E_{fi}) Equation 3

Where W is the transition rate, is the reduced Planck constant, V_{fi} is the matrix element of the potential that operates between the initial and final value, and ρ(E_{fi}) is the DOS at the energy of the transition. Equation 3 shows that the probability of a transition depends on the DOS of the system. Therefore, inside the range of the photonic SB, where the DOS is reduced, W will be lower, producing a decrease in emission intensity and a lengthening of the lifetime. Outside this range or along different directions the transition probability will not be affected, but on the edges of the SB, if the DOS really increases, it would lead to an increase of the emission intensity and a decrease in the lifetime of the fluorophore located inside the structure.

Disclosed embodiments of the present invention proved the theoretical prediction that in the case of an emission overlapping with the photonic stop band, the intensity is redistributed at different wavelengths. This prediction has two major consequences: i) the total QY remains the same; and ii) the intensity increases just outside the band gap. For one disclosed embodiment, Eu²⁻ is the responsible emitter in a hybrid material based on GaN on silica, which has a fairly broad emission with its maximum at 500 nm. The GaN and Eu²⁺ were placed inside an inverse opal of silica (air voids in silica matrix). The size of the holes in the different samples was varied between 300 and 600 nm, in order to tune the stop band in different positions with respect to the Eu²⁺ emission. The measured quantum yield was constant for the different samples at about 5%, the lifetime of the Eu²⁺ increased in the forbidden range, and its emission intensity was squeezed towards the side of the stop band, with a concomitant decrease of the lifetime. The enhancement of the emission intensity at a certain energy range opens new possibilities for the design of more efficient devices, providing color purification and intensification at whichever wavelength is needed.

### IV. Examples

The following examples are provided to illustrate certain features of working embodiments of the present invention. A person of ordinary skill in the art will appreciate that the scope of the invention is not limited to the particular features exemplified by the working examples.

### Example 1

### A. Materials

Ga(NO₃)₃.xH₂O, Mg(NO₃)₂.6H₂O, La(NO₃)₃.6H₂O, Eu(NO₃)₃.5H₂O, glycine, and trioctylphosphine (90%) were purchased from Aldrich and used as received. Aqueous ammonium hydroxide (28-30%) was purchased from Merck. The anhydrous ammonia gas (99.999%) used for the nitridation was purchased from Praxair. Milli-Q™ water with resistance greater than 18 MΩ was used in all our experiments.

### B. Preparation of Mg²⁺-Doped Gallium Oxide Nanoparticles

Mg²⁺-doped gallium oxide nanoparticles were prepared by the glycine-nitrate combustion method. Stoichiometric amounts of Ga(NO₃)₃.xH₂O (1.25 mmol, assuming x=8), Mg(NO₃)₂.6H₂O (0.20 mmol), and glycine were dissolved in 25 ml of water by keeping a glycine to metal ion ratio of 1.2. The solution was slowly evaporated at 120° C., until a transparent residue was obtained. This was then heated to 220° C. The combustion reaction took place and a brownish-yellow coloured product was obtained. The resulting solid was then heated in a flowing air at 650° C. for 5 hours to get white Mg²⁺-doped gallium oxide nanoparticles.

### C. Preparation of Eu³⁺ (5%)-Doped La₂O₃ Powder

An aqueous solution was prepared by dissolving corresponding amounts of La(NO₃)₃.6H₂O and Eu(NO₃)₃.5H₂O. This solution was added drop wise to the flask containing 10 ml of 28% NH₄OH solution. The precipitate was washed well with Milli-Q™ water and dried in vacuum and then converted to Eu³⁺-doped La₂O₃ by heating in air at 950° C. for 12 hours.

### D. Preparation of Mg²⁺-Doped GaN Nanoparticles

In a typical example, nanoparticles of Mg²⁺-doped gallium oxide were mixed with Eu³⁺-doped La₂O₃ powder in the ratio 1:10 (w/w) and grounded well for proper mixing. This oxide mixture was taken in a quartz crucible and placed inside a quartz furnace. The nitridation was performed in an ammonia atmosphere. The temperature of the furnace was increased to 950° C. at a rate of 5° C./minute. This temperature was maintained for 3 h before it was cooled down to room temperature (RT) at the same rate in the NH₃ atmosphere. The NH₃ flow was maintained at 10 SCCM (cubic centimeter per minute at standard temperature and pressure (STP). The resultant light yellowish white product was digested in 10% HNO₃ solution for 1 hour to remove all the La₂O₃ and MgO. The residue was washed with water, and methanol followed by drying under vacuum. The yield of GaN was essentially quantitative.

E. Coating Mg²⁺-Doped GaN Nanoparticles with TOPO

The dried Mg²⁺-doped GaN nanoparticles (15 mg) were mixed with 1.50 g of trioctylphosphine oxide (TOPO) and refluxed for 24 hours at 220° C. in an argon atmosphere. The resulting solid was washed well with methanol to remove any uncoordinated TOPO. The nanoparticles were finally dispersed in absolute ethanol.

### F. X-Ray Powder Diffraction (XRD) Studies

Approximately 40-50 mg of the sample was gently stirred in an alumina mortar to break up lumps. The powder was smeared on to a zero-diffraction quartz plate using ethanol. Step-scan X-ray powder-diffraction data were collected over the 2θ range 3-100° with CuKα (40 kV, 40 mA) radiation on a Siemens D5000 Bragg-Brentano θ-2θ diffractometer equipped with a diffracted-beam graphite monochromator crystal, 2 mm (1°) divergence and anti-scatter slits, 0.6 mm receiving slit, and incident beam Soller slit. The scanning step size was 0.04°2θ with a counting time of 2 s/step.

### G. AFM Measurements.

Atomic force microscopy (AMF) images were recorded in the contact mode using a Thermo microscope AFM scanner having a silicon nitride tip (model MLCT-EXMT-A) supplied by Veeco Instruments. The nanoparticles were dispersed in absolute ethanol and sonicated for an hour before depositing on a thin glass plate (5×5 mm²) by placing a drop of the dispersion followed by slow drying in air for ca. 1 h to avoid the capillary interactions during the drying process. The measurements were done with a resolution of 500×500 pixels per image and an image dimension of 50×50 μm². For the histogram analysis only particles which were smaller than 100 nm were taken. The reported values were based on the heights of the AFM features.

### H. Photo Luminescence (PL) Measurements

Room temperature PL measurements on the Mg²⁺-doped GaN samples were performed using a 325 nm Omnichrome Series 74 He—Cd Laser by Melles Griot. The laser beam was focused on the Mg²⁺-doped GaN particles through the microscope. A SpectroPro-500™ monochromator by Acton Research Corporation was used to scan the Photoluminescence signal in the visible range (350 nm-700 nm). The signal was amplified by a differential preamplifier and then acquired by the computer. The PL studies of the Eu³⁺-doped La₂O₃ samples were carried out using an Edinburgh Instruments' FLS 920 instrument with a 450 W Xe arc lamp and a red-sensitive Peltier-element-cooled Hamamatsu R928P PMT. The measurement was done using a solid sample holder. A KBr pellet was prepared by mixing the sample and the KBr in the ratio 1:10 and placed in a solid sample holder. The emission from the sample was collected from the reverse side of the pellet at an angle 30° with respect to source and normal to the sample surface. All spectra were recorded with 1 nm resolution and corrected for the instrument response.

### I. Results and Discussion.

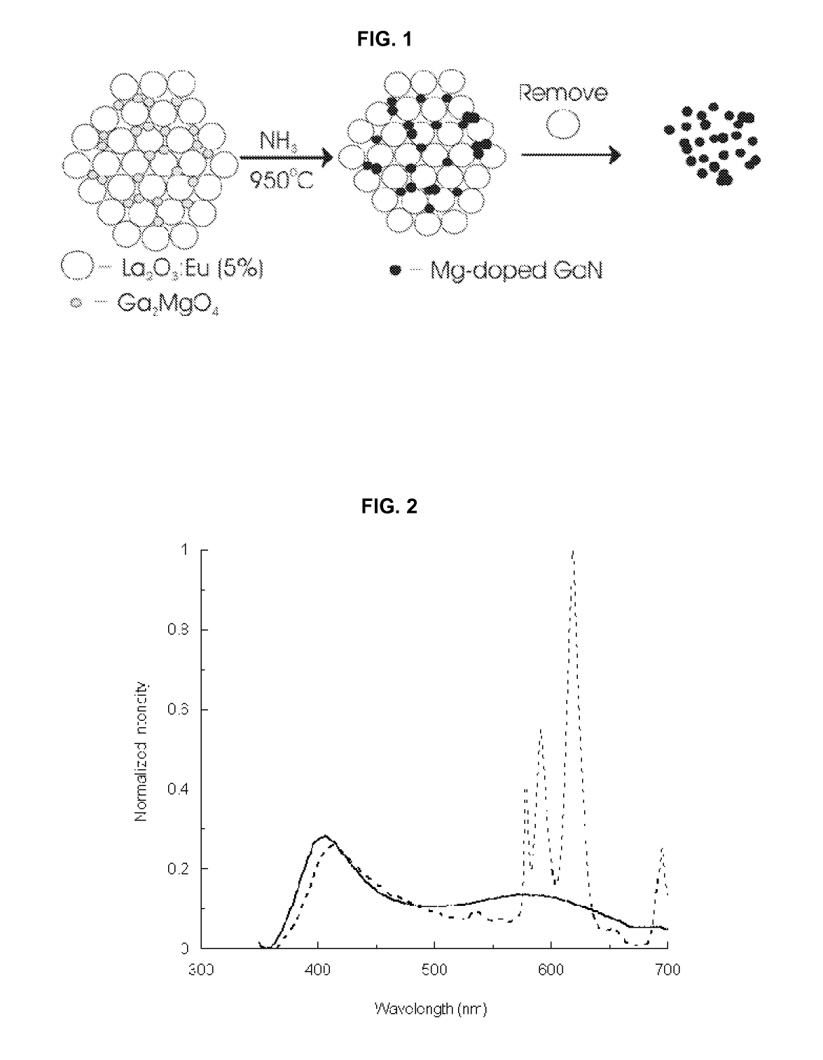

FIG. 1 illustrates the various steps involved in the synthesis of nanoparticles according to the present invention, as exemplified by synthesis of Mg²-doped GaN nanoparticles. First, the Mg²⁺-doped gallium oxide nanoparticles prepared by combustion method were mixed with a La₂O₃ matrix at a mass ratio of 1:10. These oxide mixtures were then exposed to NH₃ atmosphere at 950° C. for 3 hours. This resulted in the formation of Mg²⁻-doped GaN nanoparticles, which were subsequently separated from the matrix by removing the matrix with 10% nitric acid.

The Mg²⁺-doped gallium oxide nanoparticles were prepared using the combustion method. During the combustion synthesis, highly exothermic reaction between the oxidant (nitrate ions) and fuel (glycine) results in the localized heating, thereby forming the nanoparticles without much sintering. XRD pattern of the nanoparticles revealed the formation of Mg²⁺-doped gallium oxide and AFM analysis indicates that the average particle size was ˜6 nm.

FIG. 2 shows the emission spectra for Mg²⁻-doped GaN nanoparticles before and after removal of the matrix. The emission spectrum of Mg²⁺-doped GaN before removal of the matrix exhibited a peak at 410 nm along with some sharp emission peaks at 578, 591, and 619 nm. The latter three peaks arose from the Eu³⁻ ions that were doped inside the La₂O₃ matrix (vide infra). These sharp peaks were assigned to the ⁵D₀→⁷F_{0,1,2} transitions, respectively. After nitric acid treatment, the sharp emission peaks corresponding to the Eu³⁺ emissions were absent indicating the complete removal of the matrix. This also indicates that no Eu³ ions diffused into the GaN material during the nitridation step. The emission peak at 410 nm was retained with a less intense broad band around 580 nm. The emission observed around 410 nm was from Mg²⁺-doped GaN. To verify that the emission was originating due to Mg²⁻ doping in the GaN matrix, prepared GaN nanoparticles were prepared without magnesium doping under identical conditions. This sample exhibited a sharp emission near 385 nm which was attributed to the band-edge emission. For comparison, the emission spectrum of GaN along with that of Mg²⁺-doped GaN nanoparticles were determined The emission spectrum collected from Mg²⁺-doped GaN nanoparticles was red-shifted by 25 nm. This shift was attributed to the Mg²⁺ doping of the GaN matrix. The emission of the Mg²⁺-doped GaN nanoparticles was much stronger than of the GaN nanoparticles.

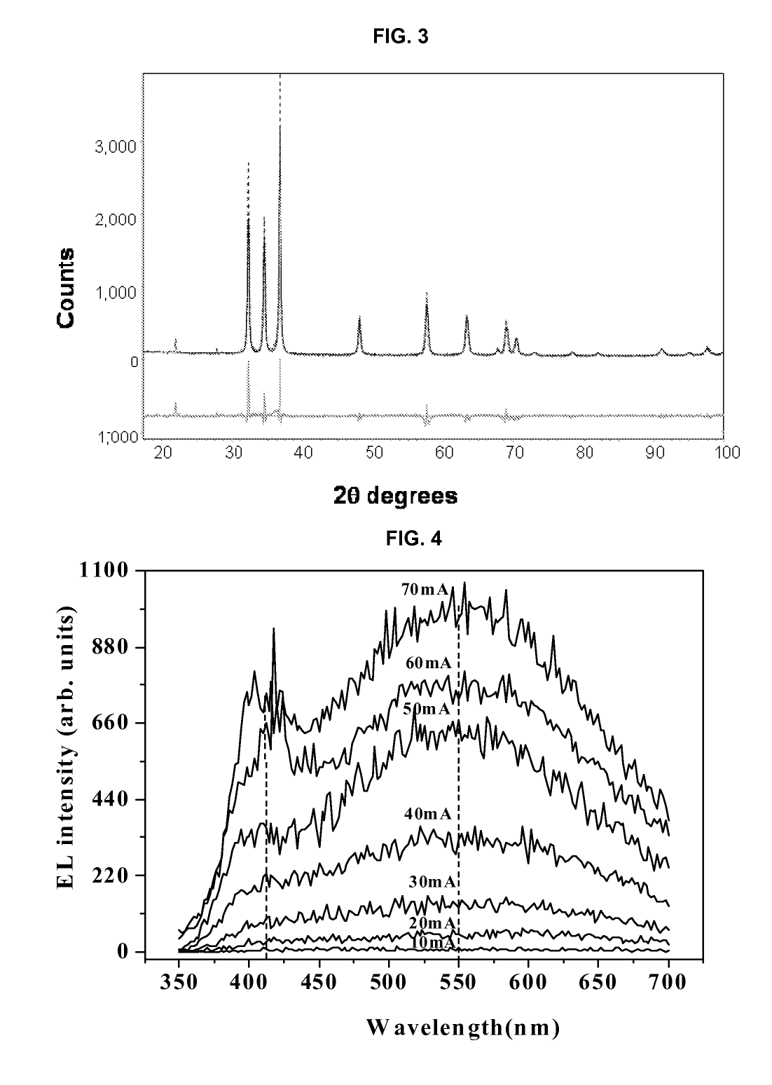

The formation of the wurtzite phase of GaN was indicated by the XRD pattern displayed in FIG. 3. The peaks appearing at the 2θ values 33, 35 and 37 were respectively assigned to (100), (002) and (101) peaks of the nanocrystalline GaN. The lattice parameters [a=3.18298 (47); c=5.17706 (93)] for undoped GaN increased to [a=3.19217 (55); c=5.18476 (93)] for Mg-doped GaN. This slight increase in the lattice parameter can be attributed to the incorporation of magnesium ions in GaN at a Ga³⁺ site or an interstitial site. In the Mg²⁺-doped GaN samples prepared without the La₂O₃ matrix a 5% MgO (periclase) phase in the XRD pattern was observed. This implies that some MgO had formed as a separate phase. This phase separation happened during the nitridation. The absence of any observation of MgO phase for the Mg²⁺-doped GaN nanoparticles prepared with the La₂O₃ matrix indicates that the nitric acid treatment employed to remove the La₂O₃ matrix etches the MgO as well. The formation of the GaN and the complete removal of the matrix (Eu³⁺-doped La₂O₃) after nitric acid treatment were also substantiated by infrared measurements. The presence of strong stretching at 575 cm⁻¹, characteristic of Ga—N and no peaks corresponding to the lanthanum oxide matrix were observed. The presence of magnesium in the Mg²⁺-doped GaN nanoparticles after the nitric acid treatment was verified by EDS analysis. The EDS results indicate that the ratio of Ga to Mg was close to 16:1, suggesting a doping level of ˜6.0% Mg in GaN. This ratio was very close to the expected value calculated from the weight percent of magnesium in Mg²⁺-doped gallium oxide nanoparticles and taking into account the 5% MgO phase that was formed during the nitridation (vide supra).

The absence of any remarkable change in the La₂O₃ matrix during the nitridation of Mg²⁺-doped gallium oxide was confirmed by the emission analysis. No change in the Eu³⁺ emission pattern, which was very sensitive to the environment, was observed for the as-prepared Eu³⁺-doped La₂O₃ and after nitridation in NH₃ at 950° C. This was further supported by the X-ray diffraction studies which indicate hardly any change in the La₂O₃ patterns before and after nitridation at 900° C.

To study the effect of using matrix in avoiding the sintering of nanoparticles during high temperature nitridation, the Mg²⁺-doped GaN nanoparticles after removal of the matrix were coated with TOPO to improve their dispersability in organic medium. TOPO was used in a subsequent step as a coordinating ligand for GaN nanoparticles. The attachment of TOPO to the surface of the GaN was verified by infrared analysis: a strong C—H stretch absorption was observed, in addition to a weak signal at 1125 cm⁻¹ for the P═O stretching frequency). The AFM images of the TOPO-coated Mg²⁺-doped GaN nanoparticles that were prepared with and without La₂O₃ matrix clearly substantiate that the Mg²⁺-doped GaN nanoparticles prepared with matrix show much less sintering compared to the nanoparticles prepared without matrix. Though some aggregation of nanoparticles was observed for the synthesis in the matrix, it was much less compared to the GaN particles prepared without the La₂O₃ matrix. This was substantiated by histogram analysis, that showed that GaN nanoparticles prepared with the matrix had an average nanoparticle size of 20 nm. For GaN particles prepared without the matrix the histogram indicates formation of larger size particles with multiple distributions. Moreover, the AFM image of the Mg²⁺-doped GaN nanoparticles prepared without the matrix indicates the formation of larger aggregates (˜200 nm in size). These results highlight the importance of the La₂O₃ matrix in avoiding the sintering of Mg²⁺-doped GaN nanoparticles to a greater extent during high temperature nitridation. Though this matrix method avoids sintering of nanoparticles into larger clusters, sintering of 2 to 3 nanoparticles was inevitable as the void sizes between the La₂O₃ matrix particles were larger than the average size of Mg²-doped gallium oxide nanoparticles. This was clear from the increase in the average nanoparticle size to 20 nm after nitridation of the 8 nm precursor Mg²⁺-doped gallium oxide nanoparticles. This method is easily optimized by: (i) increasing the mass ratio of La₂O₃ matrix to the precursor oxide nanoparticles; (ii) matching the void sizes formed between the La₂O₃ particles to the size of the precursor particles; and (iii) developing co-precipitation methods where the precursor nanoparticles were prepared during the synthesis of the matrix materials.

### Example 2

The EL devices with a configuration of indium tin oxide (ITO)/poly(3,4-ethylene dioxythiophene) doped with poly(styrenesulphonic acid) (PEDOT:PSS)/GaN:Mg NCs/Ca/Al were fabricated using a spin-coating method. The average size of the GaN:Mg NCs was estimated using transmission electron microscopy (TEM) image. The NCs had sizes in the range of 15-35 nm. X-ray diffraction (XRD) analysis confirmed the formation of the hexagonal GaN wurtzite phase. Briefly, poly(3,4-ethylene dioxythiophene) doped with poly(styrenesulphonic acid) (PEDOT:PSS) was spin-coated on a clean surface of a patterned ITO covered glass substrate, followed by 15 minutes soft baking at 110° C. in vacuum (<10 torr). Subsequently, a dispersion of GaN:Mg NCs (4 mg/ml) in iso-propanol:chloroform (1:1, v/v) was ultra-sonicated for 2 hours, spin-coated on top of the PEDOT:PSS layer, and dried in vacuum (<10 torr) oven at 60° C. overnight. The iso-propanol:chloroform mixture did not dissolve the PEDOT:PSS blend. Finally, the metal cathode (20 nm Ca and 150 nm Al) was thermally evaporated onto the NCs layer at <5×10⁻⁵ torr using a shadow mask to complete the device. The devices having an active area ˜7.5 mm² were connected to a direct current (dc) voltage supply (Keithley 2400 source meter) with the positive terminal attached to the ITO electrode. EL spectrum was measured using an Edinburgh Instruments' FLS 920 fluorescence spectrometer. All the device fabrication and characterization steps were carried out under ambient conditions.

The work functions of ITO, PEDOT:PSS and Ca/Al electrodes were values reported in the literature. The electron affinity of GaN:Mg nanocrystals was taken from previous experimental data of p-type GaN. The energy gap of 3.0 eV was based on the emission at 410 nm. In the EL device, holes were injected from the ITO electrode through PEDOT:PSS layer into the NCs. Similarly, the electrons were considered to be injected from the Ca/Al electrode into the NCs layer. The electron-hole pairs combine on nanocrystal layer releasing energy as emission light.

The PEDOT:PSS was chosen as a hole injection/transport layer because of its many advantages, such as a high transparency, excellent thermal stability and high conductivity. The current-voltage (I-V) characteristics of the GaN:Mg EL device exhibited a diode-like behavior. The EL emission was only found under a forward bias, i.e. when a positive voltage was applied to the ITO electrode. As a reference, the threshold voltage of the PEDOT:PSS-only device was measured and found to be around 2.5 V, whereas the threshold voltage of GaN:Mg EL device was increased to 5 V. Increased threshold voltage suggests that there was a higher barrier for charge injection from electrodes into the GaN:Mg layer. For further investigation, I-V curve of another device without PEDOT:PSS, i.e. a device with a configuration of ITO/GaN:Mg/Ca/Al was fabricated, which exhibits only a conductor behavior, indicating that the PEDOT:PSS was necessary to lower the energy barrier for hole injection from ITO to GaN:Mg layer.

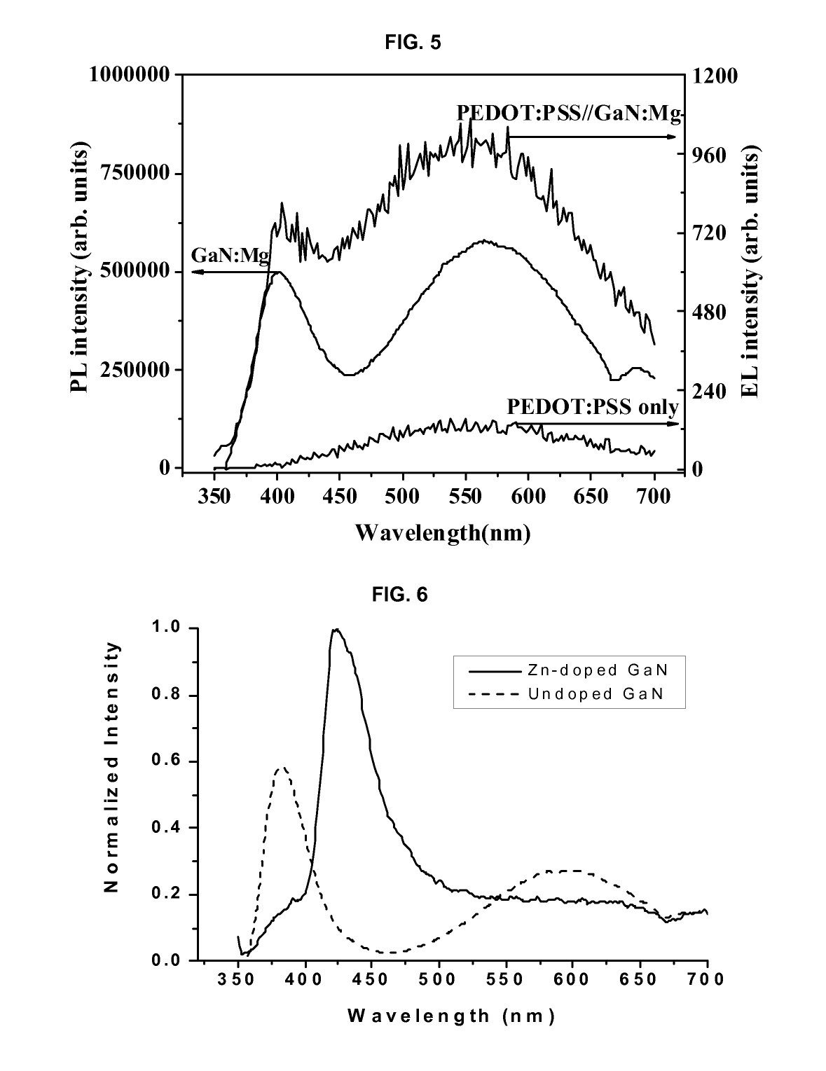

EL spectra as a function of applied currents from the device with a configuration of ITO/PEDOT:PSS/GaN:Mg/Ca/Al were displayed in FIG. 4. An interesting aspect was that the spectra showed a voltage-dependent behavior. The emission intensity increased with increased applied voltage with some change in emission wavelength. At lower voltages, the emission appears preferentially at longer wavelengths with a broad maximum wavelength around 570 nm, whereas at higher voltages the emission of 410 nm appears. Only a very weak emission around 530-570 nm was found from a control device consisting of ITO/PEDOT:PSS/Ca/Al (FIG. 5). This indicates that the broad emission probably occurred in the PEDOT:PSS layer at lower voltages. When the voltage was high enough, EL emission from GaN:Mg NCs was clearly observed. EL emission peaks at 70 mA almost cover all the visible regions of the spectrum. The calculated CIE (Commission International de l'Eclairage) coordinates from EL spectrum of 70 mA in FIG. 4 were 0.35 and 0.39, well within the white region of 1931 CIE diagram. This white light can be seen by the naked eye. No noticeable EL emission was found in the absence of the PEDOT:PSS layer.

As a comparison, the PL emission from GaN:Mg nanocrystals excited with a 325 nm He—Cd laser at room temperature is also provided in FIG. 5. The PL spectrum shows a peak at 410 nm with a broad band around 565 nm. The EL spectrum matches well with the PL spectrum of GaN:Mg NCs. The emission observed around 410 nm was attributed to the donor-acceptor pair recombination from GaN:Mg NCs¹⁸ and the broad emission centered at 565 nm was assigned to the well-known yellow emission from GaN. The origin of the latter emission was, however, still under debate. Without being bound to theory, the broad emission in our devices most likely arose due to the presence of defects at the surfaces, which could in principle be minimized by subsequent surface chemistry or tuning the preparation conditions such that the synthesis leads to reduced defects on the nanocrystal surfaces. If the broad emission near 565 nm is effectively depressed, it is also possible to make a blue light-emitting device with GaN:Mg NCs. The good correlation between the EL and PL emission peaks suggest that electron-hole recombination indeed occurred in the GaN:Mg nanocrystals layer. However, the intensity of long wavelength emission peak was enhanced due to the EL from PEDOT:PSS in the long wavelength of ˜550 nm. The EL spectrum in FIG. 5 can be fit by the PL emission of the GaN:Mg NCs and EL spectrum of PEDOT:PSS. This reveals that the EL was both from the nanocrystals and the polymer layers, due to the recombination in both components, but the EL emission of GaN:Mg nanocrystals was the dominate one at higher voltages.

### Example 3

### A. Materials

Ga(NO₃)₃.xH₂O, Mg(NO₃)₂.6H₂O, Zn(NO₃)₂.6H₂O, tetraethylorthosilicate (TEOS), and glycine were purchased from Aldrich and used as received. The anhydrous ammonia gas (99.999%) used for the nitridation was purchased from Praxair. Milli-Q™ water with resistance greater than 18 MΩ was used in all our experiments.

### B. Preparation of Oxide Precursors

The Mg²⁺- and Zn²⁺-doped gallium oxide precursors were prepared by the combustion method, which has been reported elsewhere. Briefly, stoichiometric amounts of Ga(NO₃)₃.xH₂O (1.25 mmol, assuming x-8), Mg(NO₃)₂.6H₂O (0.20 mmol) or Zn(NO₃)₂.6H₂O (0.20 mmol), and glycine were dissolved in 25 ml of water by keeping a glycine-to-metal ion ratio of 1.2. The solution was slowly evaporated at 120° C., until a transparent residue was obtained. This was then heated to 220° C. The combustion reaction took place and a brownish-yellow coloured product was obtained. The resulting solid was then heated in a flowing air at 650° C. for 5 hours to get white Mg²⁺-doped gallium oxide or Ga₂ZnO₄ nanoparticles.

### C. Preparation of Mg²⁺- and Zn²⁺-Doped GaN Nanoparticles

Nanoparticles of Mg²⁺-doped gallium oxide or Zn²⁺-doped gallium oxide in a quartz crucible were placed inside a quartz furnace. Nitridation was performed in an ammonia atmosphere. The temperature of the furnace was increased to 950° C. at a rate of 5° C./minute. This temperature was maintained for 3 hours before it was cooled down to RT at the same rate in the NH₃ atmosphere. The NH₃ flow was maintained at 10 SCCM (cubic centimeter per minute at STP).

### D. Silica Coating on the GaN Nanoparticles

To coat a thin layer of silica over the GaN nanoparticles (M²⁺ doped, such as Mg²⁺- or Zn²⁺-doped), roughly 25 mg of the corresponding nanoparticles were dispersed in 75 ml ethanol and sonicated for 2 hours. After sonication, the supernatant was removed after the dispersion was undisturbed for an hour. To the above mixture, 23.5 ml water, 1.5 ml NH₄OH, and 50 μl of TEOS were added and stirred overnight.

### E. X-Ray Powder Diffraction (XRD) Measurements

The XRD patterns of the Mg²⁺- and Zn²⁺-doped GaN nanoparticles were collected using a Rigaku Miniflux™ X-ray diffractometer with a Cr K_{α} (30 kV, 15 mA) radiation source. The nanoparticle samples were gently crushed before being smeared on to a clean quartz slide. The powder diffraction patterns were collected over the 2θ range 20 to 140° with a scan speed and sampling width of 1°/minute and 0.02°, respectively.

### F. Raman Spectroscopic Measurements

Raman spectra were collected by exciting the sample with 632.8 nm He—Ne Laser by Melles Griot. The solid sample was evenly spread over a clean glass slide. Each spectrum was collected over 30 seconds and were expressed as an average of 6 scans.

### G. X-Ray Photoelectron Spectroscopy (XPS) Measurements

X-ray photoelectron spectra were collected using a Leybold Max200™ spectrometer, using monochromatic Al K_{α} X-ray source (1486.6 eV). The pass energy for the survey and narrow scans were 192 and 48 eV, respectively. Photoelectrons were collected at 90° from the surface. All binding energies (BE) were reported relative to the C1s peak (BE: 285.0 eV).

### H. Transmission Electron Microscopic (TEM) Measurements

The TEM images were collected using a Hitachi H-7000 tungsten filament up to 125 kV Transmission Electron Microscope. TEM specimens were prepared by dipping a copper grid (600 mesh), which was coated with an amorphous carbon film into the ethanol dispersion of the silica-coated GaN:Mg nanoparticles, followed by slow drying at room temperature.

### I. Photo Luminescence (PL) Measurements

Room temperature PL measurements on the Mg²⁺- and Zn²⁺-doped GaN samples were performed using a 325 nm Omnichrome Series 74 He—Cd Laser by Melles Griot. The laser beam was focused on the Mg²⁺-doped GaN particles through the microscope. A SpectroPro-500 monochromator by Acton Research Corporation was used to scan the Photoluminescence signal in the visible range (350 nm-700 nm). The signal was amplified by a differential preamplifier and then acquired by the computer.

### J. Results and Discussion

The Mg²⁺- and Zn²⁺-doped GaN nanoparticles were prepared by a solid state reaction, involving nitridation of the corresponding oxides, such as Mg²⁺-doped gallium oxide or Zn²⁺-doped gallium oxide nanoparticles, which were produced by the glycine combustion method to yield small nanoparticles typically in the size range of from about 5 to about 10 nm. The XRD pattern of the Zn²⁺-doped GaN nanoparticles clearly confirms the crystalline GaN with wurtzite structure. Both Mg²⁺- and Zn²⁺-doped GaN nanoparticles exhibit a bright blue emission at 425 nm when excited at 325 nm. This PL peak position is red-shifted by roughly 50 nm with respect to the undoped GaN nanoparticles. For example, FIG. 6 displays the emission spectra of Zn²⁺ (3%)-doped GaN nanoparticles and the undoped GaN nanoparticles. The shift in the emission was attributed to the doping of Zn²⁺ ions into the GaN matrix. Upon excitation in the UV region, most of the electrons from the conduction band non-radiatively relaxed to the defect level from where the PL originates. It was also possible that few electrons from the conduction band edge relaxed directly to the ground state. This led to the band edge emission near 375 nm appearing as a shoulder. In addition to these peaks, there was also a broad band observed around 600 nm, which was more pronounced in the case of undoped GaN nanoparticles compared to Zn²⁻-doped nanoparticles. This was normally denoted as the “yellow emission” and assigned to the certain type of defects in the GaN lattice (vide infra).

To compare the optical characteristics of Mg²⁺- and Zn²⁺-doped GaN nanoparticles, samples comprising a doping level of 3% were prepared under identical conditions. The PL spectra of the Mg²⁺ (3%)-doped GaN nanoparticles compared with the corresponding Zn²⁺-doped nanoparticles showed that the main PL peak for both Mg²⁺- and Zn²⁺-doped GaN nanoparticles appeared at 425 nm; however, the emission spectrum of the Zn²⁺-doped GaN nanoparticles showed additional shoulder towards longer wavelength. Moreover, the Gaussian fitting of the emission peaks of Zn²⁺-doped nanoparticles shows two peaks with peak maximum centering at 427 and 458 nm. Moreover, the Gaussian fitting of the emission peaks of Zn²⁻-doped nanoparticles showed two peaks with peak maximum centering at 427 and 458 nm. Without being bound to a theory of operation, the multiple peaks could be attributed to the presence of additional defect states created by the incorporation of zinc ions into the GaN matrix. The sharp emission at 427 nm may arise from the Zn_{Ga}, whereas the origin of the emission near 458 nm was attributed to the zinc ions at the nitrogen vacancy. This difference in the luminescence was possibly due to the difference reactivity (solubility) of the Mg²⁺ and Zn²⁺ ions during the growth of GaN nanoparticles.

The difference in the optical properties between the Mg²⁺- and Zn²⁺-doped GaN nanoparticles was not only limited to the difference in the shape of the PL peak but also on the defect-related yellow emission as well as on the observed PL trend for different doping levels (see below). As was observed for Zn²⁺ and undoped GaN, the observed yellow emission near 580 nm was predominant in the Mg²⁺-doped GaN compared to Zn²⁺-doped nanoparticles. Without being bound to a theory of operation, Mg²⁺ doping appears to create more defects on the GaN lattice compared to the Zn²⁺-doped GaN nanoparticles most likely closer to the surface of the nanoparticles. The latter was true as the size of the nanoparticles was roughly in the range of 12-15 nm. The presence of more lattice defects in Mg²⁺-doped GaN nanoparticles was substantiated with the Raman analysis (see below).

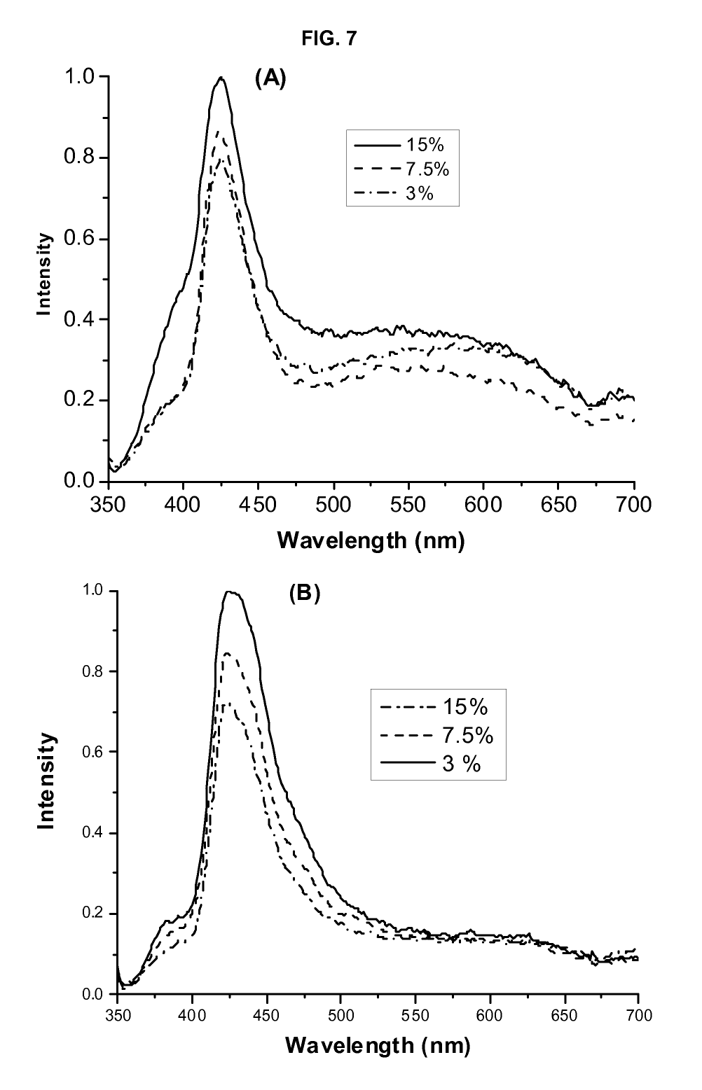

FIG. 7 shows the PL tread observed in Mg²⁺- and Zn²⁺-doped GaN samples with different doping concentrations. Mg²⁺-doped samples showed a slight reduction in the intensity with the decrease in the Mg²⁺ concentration, whereas the opposite effect was observed for the Zn²⁺-doped GaN nanoparticles (FIG. 7b). The preferred location for the Mg²⁺ in GaN was magnesium in the gallium site (Mg_{Ga}). These results suggest that increasing the doping concentration increases the probability of incorporation of Mg²⁺ into GaN lattice. Thus the increase in the concentration of the Zn²⁺ might increase the probability for the creation of additional defect states. Though this explanation is tentative, the observed PL behavior is attributed to the different origin of the emission.

To get more insight on the structural characteristics, Raman and XPS analyses were performed. All spectra displayed a strong peak at 570 cm⁻¹, which was the characteristic E₂ phonon frequency of the host GaN. Additionally, the spectra showed few other weak bands at 530 cm⁻¹, 650 and 727 cm⁻¹. The peak at 530 cm⁻¹ was assigned to the A₁ optical modes and the latter two bands were attributed to the disorder-activated Raman scattering. These disorder-activated bands were originally Raman inactive modes and their appearance was ascribed to the distortion in the lattice structure. As it was clear from the Raman spectra the peak at 727 cm⁻¹ was more intense in the Mg-doped GaN compared to the Zn-doped samples and it was quite weak in the undoped GaN nanoparticles. This clearly implies that there was more lattice rearrangement in the case of Mg²⁻-doped GaN compared to Zn²⁺- and undoped GaN samples.

XPS analysis was performed to obtain details on the elemental composition. The Ga 3d and N1s region of the XPS spectra showed that the Ga 3d peak appeared at a binding energy (BE) of 20.1 eV and the nitrogen 1s at 397.2 eV. This was consistent with the value obtained for GaN nanorods. There was hardly any change in the BE positions of Ga 3d or N 1s after incorporation of Mg²⁺, which might be due to the small amount of Mg²⁺ incorporation. To get a clearer picture on the effect of increase in magnesium doping concentration, the atomic ratios of Mg-to-N, Ga-to-N, and Mg-to-Ga were plotted against the doping amounts of the magnesium. The graph indicated that both the Mg/Ga and Mg/N ratios increased with the increasing Mg²⁺ concentration, whereas the Ga/N ratio dropped for 3% doping and slightly increased before decreasing again. Without being bound to theory, the slight decrease in the ratio of the Ga/N for all Mg²⁻-doped GaN samples compared to the undoped GaN nanoparticles along with the increase in the Mg/N and Mg/Ga ratio suggests that the most likely location of the Mg²⁺ ions in the GaN lattice was the gallium site. Though a steady increase has been observed in the Mg/N and Mg/Ga ratios with increase in the doping level a similar decrease was not observed with the Ga/N ratio. Without being bound to theory, this is probably because with the increase in the Mg²⁺ concentration, the Mg²⁻ ions prefer to occupy the interstitial sites, as the size of the Mg²⁺ is slightly larger than the Ga³⁺ ion.

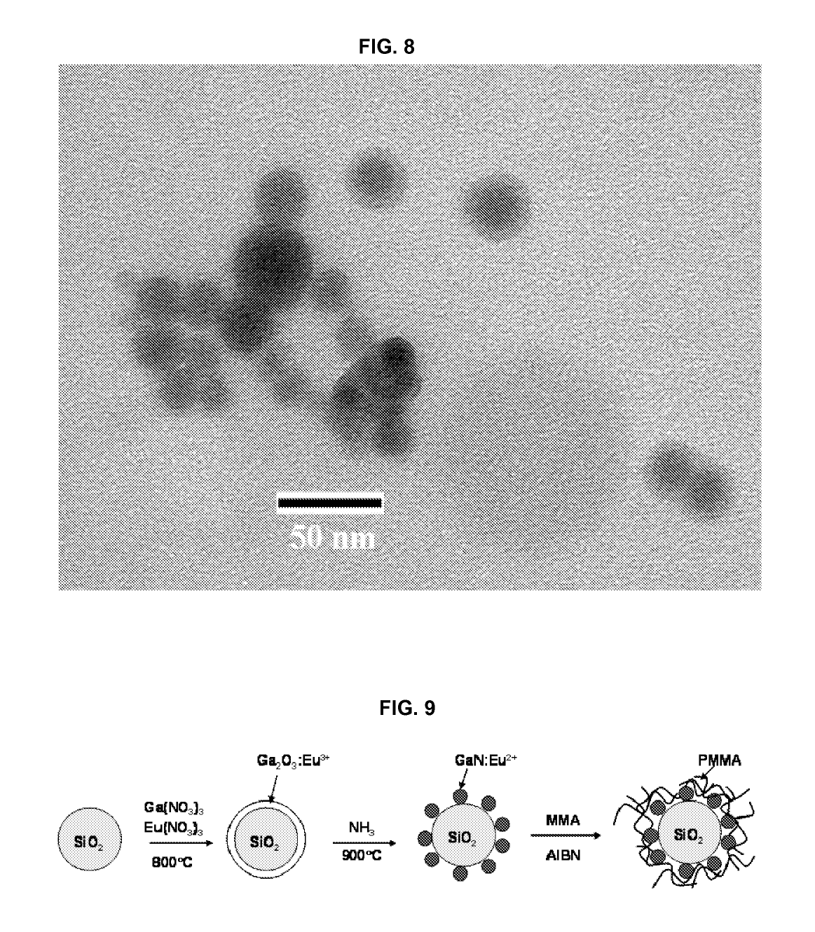

Having studied the structural and optical properties of the Mg²⁺- and Zn²⁺-doped GaN nanoparticles, applications of the technology were examined. One of the applications was the exploitation of these GaN nanoparticles in the development of EL-based devices. The other possibility was the integration of these nitride-based semiconductor nanoparticles into biological systems. Any bio-related applications demand the need of dispersible nanoparticles. As a proof of concept, dispersability of the nanoparticles was increased by coating a thin layer of silica over the GaN nanoparticles via the well-known Stöber method. In principle, silica coating not only improves the dispersability but provide a biocompatible surface. The TEM image shown in FIG. 8 indicates a thin bright region over a dark spheres. This clearly suggests the formation of a very thin silica shell over the GaN nanoparticles. The coating of the silica shell was substantiated by the dispersability of the core/shell materials in ethanol over a period of few weeks. These core/shell materials can be utilized for attachment of bio-linkers or to grow another semiconductor shell.

### Example 4

### A. Chemicals

Tetraethyl orthosilicate, aqueous ammonium hydroxide (28-30%) gallium nitrate (99.98%), europium nitrate (99.99%), methylmethacrylate, urea, potassium bromide, and ethanol (99.9%) were used as received from Aldrich. The anhydrous ammonia gas (99.999%) used for the nitridation was purchased from Praxair. Milli-Q™ water with resistance greater than 18 MΩ was used in all examples.

### B. Preparation of Bare Silica Nanoparticles

The silica nanoparticles with an average size of 50 nm were synthesized using a literature procedure. Briefly, 3.8 ml of tetraethyl orthosilicate was added to a mixture containing 114 ml of ethanol and 5.7 ml of ammonium hydroxide (28-30%) while vigorous stirring. Stirring was continued overnight, which results in the formation of silica nanoparticles with average size of 50 nm. These silica particles were used as prepared in all the following examples.

### C. Preparation of Eu³⁺ (5%)-Doped Ga₂O₃/SiO₂ Nanocomposites

Eu (5%)-doped Ga₂O₃/SiO₂ nanocomposites were prepared by adapting a procedure reported for Gd₂O₃:Eu³⁻@SiO₂. Briefly, 0.6 g of urea dissolved in water was added to a flask containing 15 ml of 50 nm silica nanoparticles. To this mixture an aqueous solution containing Ga(NO₃)₃ and Eu(NO₃)₃ was added dropwise and vigorously stirred at 85° C. for 3 hours. The resulting white precipitate was purified by centrifugation and redispersion in water for 3 times followed by drying in vacuum. Finally, the white product was heated to 800° C. for 2 hours.

### D. Preparation of Eu²⁺ (5%)-Doped GaN/SiO₂ Nanocomposites

Approximately 100 mg of the Eu³⁺-doped Ga₂O₃/SiO₂ nanocomposites was taken in a quartz crucible and placed it in an electric furnace (Lindberg). The furnace was heated to 900° C. for 3 hours in NH₃ atmosphere at a rate of 5° C. per minute. The sample was left at the final temperature for 3 hours before it was cooled to room temperature in NH₃ atmosphere at a rate of 5° C. per minute. The ammonia flow was maintained at 10 SCCM (cubic centimeter per minute at STP). The sample color changed from colorless to yellow during this reaction process.

### E. Preparation of PMMA Coated Eu (5%) Doped GaN/SiO₂ Nanocomposites

Roughly 0.5 ml of methylmethacrylate was added to 15 mg of the Eu²⁺-doped GaN/SiO₂ nanocomposites and sonicated for 2 hours. After sonication, approximately 1 mg of azobisisobutylnitrile (AIBN) as initiator was added to the above mixture. The mixture was thermally polymerized at 72° C. for 1 hour. The resulting mixture was dispersed in toluene.

### F. Transmission Electron Microscopic (TEM) Measurements

A Hitachi H-7000 tungsten filament up to 125 kV Transmission Electron Microscope was used to collect the TEM images. TEM specimens were prepared by dipping a copper grid (600 mesh), which was coated with an amorphous carbon film into the ethanol dispersion of the nanomaterial composites, followed by drying at room temperature.

### G. Energy Dispersive X-Ray Spectroscopy (EDS)

The EDS analysis was done using an Oxford Instruments Link ISIS EDX X-ray microanalysis system on the Hitachi S-3500N Scanning Electron Microscope. The samples were gently crushed before depositing on a double sided tape.

### H. Fourier Transform Infrared (FTIR) Measurements

FTIR measurements were done using a Perkin Elmer FTIR spectrometer 1000 machine. A KBr pellet was made by mixing dried KBr and the sample approximately in the ratio 10:1. All spectra were an average of four scans and recorded with a resolution of 2 cm⁻¹.

### I. Powder X-Ray Diffraction Analysis

The solid sample was first gently crushed to break the larger clumps, and then after smeared on to a zero-diffraction quartz plate using ethanol. Step-scan X-ray powder diffraction data were collected over the 2θ range 15 to 80° with CuK_{α} (40 kV, 40 mA) radiation on a Siemens D5000 Bragg-Brentano θ-2θ diffractometer equipped with a diffracted-beam graphite monochromator crystal, 2 mm (1°) divergence and anti-scatter slits, 0.6 mm receiving slit, and incident beam Soller slit. The scanning step size was 0.04°2θ with a count time of 2 s per step.

### J. Electron Paramagnetic Resonance (EPR) Measurements

The EPR spectrum was recorded on a Bruker EMX EPR instrument operating in the X-band (9.44 GHz). The temperature was 135 K. The collected spectrum was an average of 100 scans.

### K. Photoluminescence (PL) Measurements

PL measurements were carried out using an Edinburgh Instruments' FLS 920 instrument with a 450 W Xe arc lamp and a red-sensitive Peltier-element-cooled Hamamatsu R928P PMT. The measurement was done using a solid sample holder. A KBr pellet was prepared by mixing the sample and the KBr in the ratio 1:10 and placed in a solid sample holder. The emission from the sample was collected from the reverse side of the pellet at an angle of 30° with respect to source and normal to the sample surface. All spectra were recorded with 1 nm resolution and corrected for the instrument response. The filters used were 320 nm and 435 nm respectively, for the collection of emission and the excitation spectra. The Eu³⁻ emissions were recorded by exciting the sample at 464 nm with 5 ns pulses at a frequency of 10 Hz, using a Vibrant tunable laser system (Model 355 IIb) with a Quantel Nd-YAG nanosecond pump laser. The lifetimes of the Eu²⁺ emission (at 450 nm) were collected using a nanosecond flash lamp. The lifetime decays were fitted by two-exponentials based on the following equation:

$$\frac{I ( t )}{{I}_{0}} = {B}_{0} + {\sum }_{i = 1}^{2} {A}_{i} exp ( - t / {τ}_{i} )$$

Intensities down to 1% of the initial intensities were included in the lifetime analysis and the chi-square (χ²) was 1.36.

### L. Quantum Yield Measurements

The absolute quantum yield measurements were determined using an integrating sphere (Edinburgh instruments, 150 mm in diameter coated with barium sulfate). The Eu²⁺-doped GaN/SiO₂ nanocomposites were coated with a thin layer of silica to enhance their dispersability in ethanol. Similarly, a GaN/SiO₂ composite without europium ions was also coated with silica and used as a reference sample.

The emission spectra collected from the nanocomposites before and after the silica coating were identical with respect to shape and position. Absolute error of 2% was based on duplicate measurements.

### M. Electroluminescence (EL) Device Fabrication Using Eu²⁺-Doped GaN/SiO₂ Nanocomposites.

Devices with a configuration of ITO//(Eu²⁺-doped) GaN/SiO₂//Ca//Al were fabricated as follows. First, the nanocomposites were dispersed in iso-propanol by sonicating the mixture for 6 hours. After sonication, the nanocomposites were spin-coated onto a clean indium tin oxide (ITO) glass substrate at 1500 rpm for 30 seconds under air-free conditions. The resulting film was then dried overnight in a vacuum oven at 60° C. Finally, the metal cathode (20 nm thick Ca and 150 nm Al) was thermally evaporated onto the nanocomposite layer at <5×10⁻⁵ torr using a shadow mask to complete the device. The EL was characterised using the Edinburgh Instruments' FLS 920 fluorescence spectrometer (vide supra). The DC power was supplied with a Keithley 2400 source meter.

### N. Results and Discussion.

FIG. 9 is a schematic representation of the various steps involved in disclosed working embodiments of the preparation of Eu²⁺-doped GaN/SiO₂ nanocomposites. Silica nanoparticles of 50 nm were prepared using a literature procedure (H. Hiramatsu, F. E. Osterloh, Langmuir 2003, 19, 7003.) These silica nanoparticles were formed by the hydrolysis and condensation of tetraethyl orthosilicate in the presence of NH₄OH as catalyst. These silica colloids were used as templates to grow a thin shell of Eu³⁺-doped Ga₂O₃ over them. This was achieved by first coating a hydroxide layer followed by heating at 800° C. These oxide-coated silica nanoparticles were then converted into nitrides by nitridation in an ammonia atmosphere at 900° C. for 3 hours, which resulted in the formation of small nanoparticles of Eu²⁺-doped GaN on the silica nanoparticles. The formation of the GaN was indicated by a color change of the sample from colorless to yellow after nitridation. Moreover, the Eu²⁺-doped GaN/SiO₂ nanocomposites were coated with a thin layer of PMMA to tune their dispersability in organic medium.

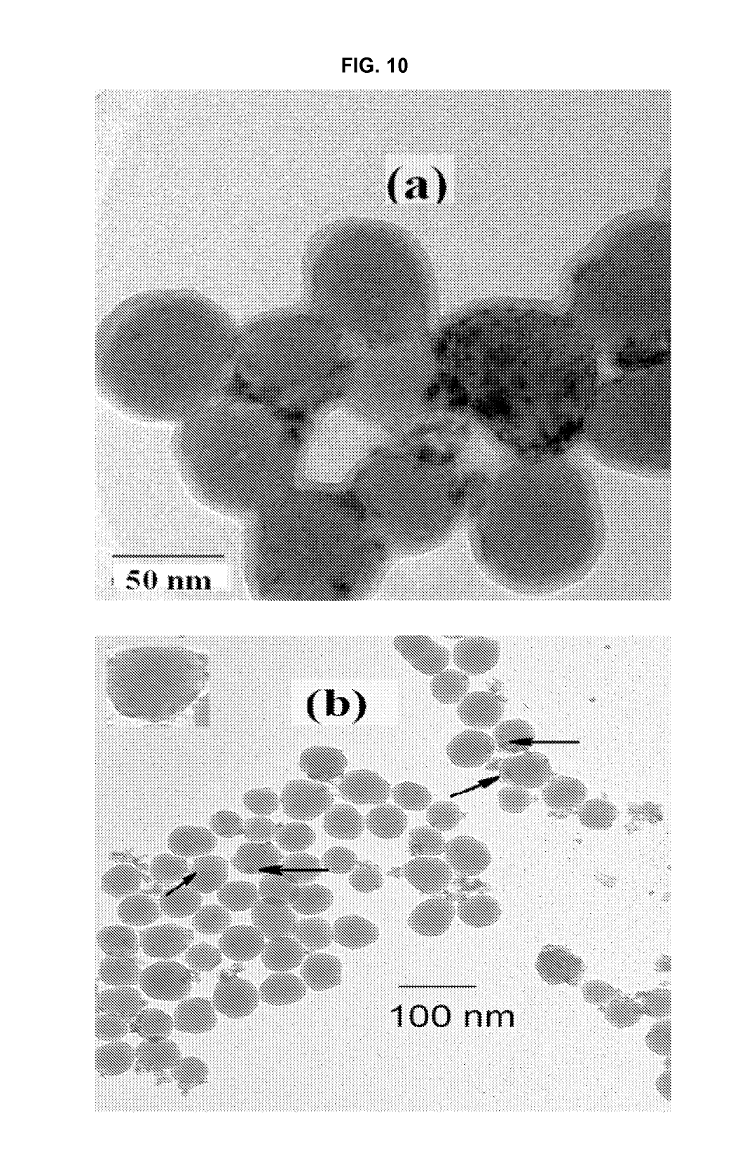

The formation of a thin shell of Ga₂O₃ on the silica surface was substantiated by the TEM image of the sample. This is shown in FIG. 10A. The image shows dark spheres coated with a lighter shell. The large dark regions correspond to the silica nanoparticles and the thin shell corresponds to Eu³⁺-doped Ga₂O₃. The image also represents some dense regions, which could be due to formation of isolated gallium oxide nanoparticles which seem still attached to the silica surface. Nitridation of the oxide precursor led to the formation of small GaN nanocrystals on the surface of silica nanoparticles as seen in TEM measurements (FIG. 10B). The image shows small dark regions of GaN nanocrystals (˜2-3 nm) on the surface of large silica nanoparticles. The image also suggests the absence of a homogeneous coating of GaN nanoparticles on the silica surface.

The formation of the hexagonal GaN on the surface of the silica nanoparticles was confirmed by XRD analysis. The XRD pattern obtained from Eu²⁻-doped GaN/SiO₂ nanocomposites showed peaks appearing at the 2θ values 37.8, 40.4 and 43.1. These were assigned, respectively, to (100), (002) and (101) peaks of the crystalline GaN. The lattice parameters for the hexagonal GaN [a=3.187(1) and c=5.183(3)] were in agreement with those reported in the literature for the bulk GaN. A broad hump observed around 25° (2θ) was from the amorphous silica. The exact nature of the silica material (nitride or oxynitride) was not clear due to the broadening of the peak but there likely was oxynitride formation (vide infra). In addition, the XRD analysis showed no evidence of any Ga₂O₃ present in the nanocomposites after nitridation indicating the complete conversion of the Ga₂O₃ present on the silica surface into GaN, although a tiny amount of crystalline or amorphous Ga₂O₃ cannot be ruled out. However, the controls argue against Ga₂O₃ as the cause of the blue emission.

EDS analysis of the Eu²⁺-doped GaN/SiO₂ showed the presence of Si, Ga, Eu, O and N. The peaks appearing at 1.098, 1.740 and 5.846 KeV correspond to the characteristic X-ray energies of GaL_{α1}, SiK_{α1} and EuL_{α1}, respectively. The atomic ratio of Ga to N was 1:2. The nitrogen concentration was twice that expected for the formation of GaN, indicating the formation of some silicon oxy nitride compound. This was also consistent with the slight decrease in the Si:O ratio from 1:2.0 to 1:1.6.

The infrared spectrum collected from the Eu²⁺-doped GaN/SiO₂ nanocomposite confirmed the presence of Si—O stretching and bending vibrations near 1100 cm⁻¹ and 450 cm⁻¹. The presence of the peak near 650 cm⁻¹ was assigned to the Ga—N stretching. In order to verify this assignment, the sample was exposed to 10% HF to etch the silica present in the nanocomposites. After exposure to HF solution for 5 hours the sample was washed well with water before drying in vacuum. The infrared measurement after etching clearly indicated the presence of a strong band at 650 cm⁻¹ which was a characteristic stretching frequency of Ga—N.

### O. Optical Properties of Eu²⁺-Doped GaN/SiO₂

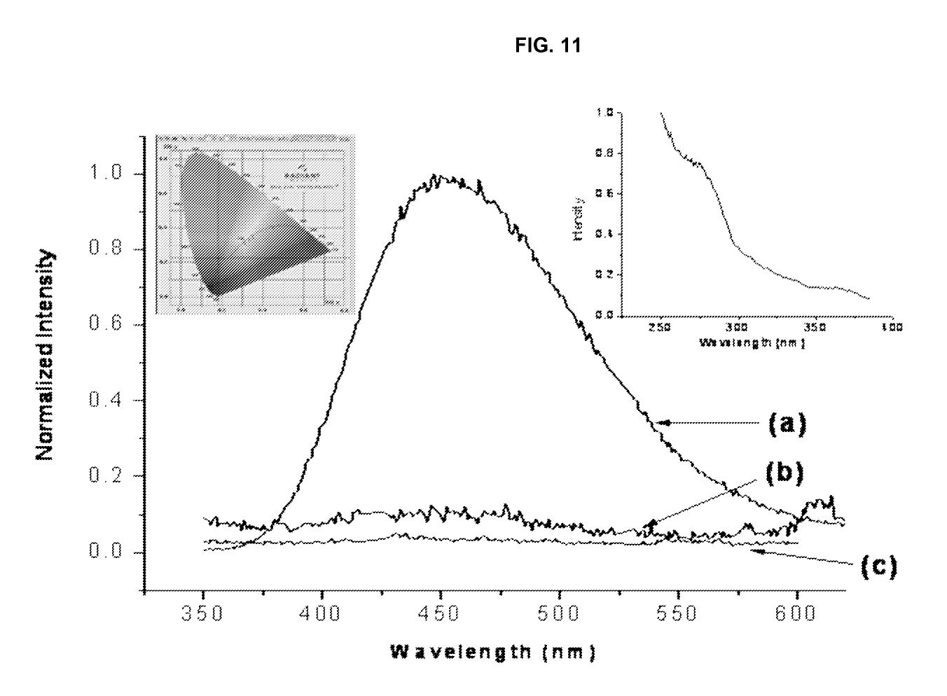

The Eu²⁺-doped GaN/SiO₂ nanocomposite when excited in the UV region exhibited a bright blue emission centered at 450 nm, as shown in FIG. 11a. The calculated CIE colour co ordinates were X=0.183 and Y=0.226, which falls well within the blue region. The excitation spectrum collected from the Eu²⁺-doped GaN/SiO₂ nanocomposites displayed broad absorptions from 250 to 300 nm (shown in the inset of FIG. 11). The measured lifetimes were 1.38 μs (80%) and 0.38 μs (20%) for the emission at 450 nm were consistent with the lifetimes reported for Eu²⁻ ions. Fast photocycles are advantageous for increased brightness for LEDs, displays, etc. The absolute quantum yield calculated using an integrating sphere for the 450 nm emission from the nanocomposites was 23±2%. The broad shape and the short lifetime of the emission peak infer that the peak does not correspond to an intra-4f transition. This was because the intra-4f electronic transitions exhibited sharp optical emissions with lifetimes in the millisecond range due to the shielding of the 4fⁿ energy levels from the surroundings by the filled 5s² and 5p⁶ energy levels and the forbidden nature of the intra 4f transition. In addition, only a weak Eu³⁺ emission was observed when excited with a laser (464 nm, absorption line of Eu³⁺) whereas the corresponding Eu³⁺-doped Ga₂O₃@SiO₂ precursor exhibits strong Eu³⁺ characteristic emissions. The narrow peaks appearing at 578, 591 and 612 nm were characteristic of the Eu³⁺ emission originating from the ⁵D₀ (excited state) to ⁷F_{J} (ground state) 4f electronic transitions. All the above observations indicate that the Eu³⁻ ions present in the Ga₂O₃@SiO₂ have been reduced to Eu²⁺ during the nitridation step. To confirm this several control experiments were performed.

First, the precursor Eu³⁺-doped as well as undoped Ga₂O₃@SiO₂ were subjected to heating at 900° C. in air to verify the presence of any defect-related emission from Ga₂O₃ or Ga₂O₃@SiO₂ as observed by others. Only a very weak emission was observed from these materials in the blue region and the Eu³⁻-doped Ga₂O₃@SiO₂ displayed only the characteristic Eu³⁺ emissions when excited in the UV region. Second, only a very weak emission was observed from the silica nanoparticles after nitridation at 900° C. in NH₃ (FIG. 11c). Finally, a GaN/SiO₂ nanocomposite was prepared by doping 5% yttrium ions instead of europium ions under similar experimental conditions. The Y³⁺ mimics the Eu³⁺ doping but was optically silent and could not be reduced to Y²⁺. The sample did not display any emission in the blue region but exhibited a broad spectrum centered at 560 nm, which could be attributed to the yellow emission from GaN. This signifies the importance of Eu²⁺ in the generation of the blue emission and rules out the possibility of band-edge or any defect-related emission from the GaN. From the control experiments discussed above it was clear that the emission observed at 450 nm was from Eu²⁺ ions and that most of the Eu³⁺ ions that were present in Ga₂O₃@SiO₂ had been converted into Eu²⁺ ions during the nitridation process.

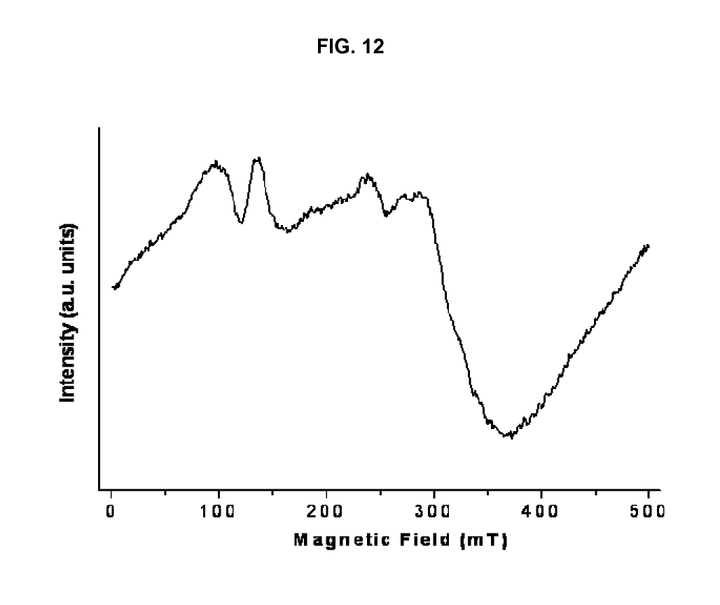

In order to get definite proof for the presence of Eu²⁺ in the europium-doped GaN/SiO₂ nanocomposites, EPR analysis was performed on the powder sample. The EPR spectrum displayed in FIG. 12 confirms the presence of Eu²⁺ in the europium-doped GaN/SiO₂ nanocomposites. The observed spectrum is similar to that obtained for the Eu²⁻-doped heavy-metal fluoride glasses (ZBLAN).

The emission from the Eu²⁺ ions is assigned to the electronic transition occurring between the 4f⁶-5d¹ excited state and ⁸S_{7/2} ground state of the Eu²⁻. This transition is an allowed transition due to mixing of 5d states with 4f states in contrast to the parity forbidden transitions within the 4f energy levels of the lanthanides. The excited state configuration 4f⁶-5d¹ is very sensitive to the host lattice (i.e. crystal field) and can occur in any part of the visible region of the electromagnetic spectrum. Earlier, Kim and Holloway (J. H. Kim, P. H. Holloway, J. Appl. Phys. 2004, 95, 4787.) observed the presence of some Eu²⁺ in Eu³⁺-doped GaN thin films prepared by radio-frequency sputtering, the origin of which was attributed to the result of preferential sputter removal of nitrogen. T. Maruyama, S. Morishima, H. Bang, K. Akimoto, Y. Nanishi, (J. Cryst. Growth 2002, 237, 1167.) observed the valence transition of Eu³⁺ to Eu²⁺ ions in GaN material. They found that the valence transition occurs to those Eu³⁺ ions that were present near the surface of GaN. To understand the location of the Eu²⁻ ions and to verify that the emission originating from the nanocomposite formed by GaN and silica in our Eu²⁻-doped GaN/SiO₂ nanocomposites we performed a control experiment where two samples, i.e., Eu₂O₃@SiO₂ and Ga₂O₃ nanoparticles were prepared separately. These two oxide samples were mixed well and subjected to nitridation at 900° C. in NH₃ atmosphere. The emission analysis of the mixed oxides after nitridation shows a weak broad emission near 500 nm. The shape and position of this emission peak is quite different from that obtained from the Eu²⁺-doped GaN/SiO₂ nanocomposites. In addition, the mixed oxides show a sharp emission at 612 nm due to the presence of Eu³⁻ ions which was not observed for the Eu²⁺-doped GaN/SiO₂ nanocomposites. Finally, Eu³⁺-doped GaN nanoparticles mixed with silica particles show only the characteristic Eu³⁺ emissions but no blue emission. These results strongly support the fact that the blue emission arises from the Eu²⁺ that are present in the nanocomposites formed by GaN and SiO₂. Due to the large size of the Eu²⁺ ions compared to Ga³⁺ ions it is reasonable to presume that they are present at the interface of GaN and SiO₂.

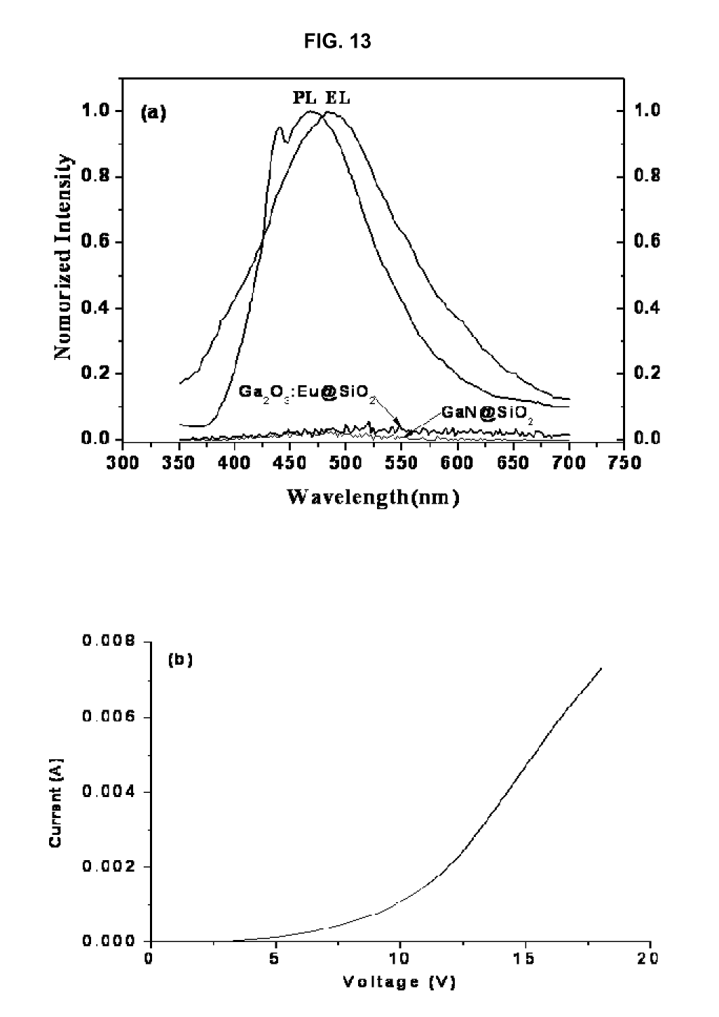

In order to take advantage of the presence of Eu²⁺-doped GaN nanoparticles on the surface of the silica nanoparticles and as a proof of principle, especially in the fabrication of thin film electroluminescence (device) (TFEL) devices, an LED device was fabricated using the Eu²⁺-doped GaN/SiO₂ nanocomposites as light-emitting material. The EL spectrum of the nanocomposites measured at 18 V was shown in FIG. 13. A broad peak centered at 485 nm dominates the EL spectrum, which was strong enough to be observed with the naked eye. The EL peak is slightly red-shift compared to the PL peak. This behavior has been observed before for nanocrystal-based EL. The reason was attributed to the local heating from the large current flux and the poor thermal conductivity of the inorganic light emitting layer. Control experiments were also performed under the identical conditions using the Eu³⁺-doped Ga₂O₃@SiO₂ as well as an undoped and Y³⁺-doped GaN/SiO₂ nanocomposites. The absence of any emission from these devices (EL measured at 18 V for GaN/SiO₂ and Eu³⁺-doped Ga₂O₃@SiO₂ are shown in FIG. 13) clearly indicate that the blue emission is originating from the Eu²⁺-doped GaN/SiO₂ nanocomposites in the LED device. The current-voltage (I-V) of a device consisting of ITO//Eu²⁺-doped GaN/SiO₂//Ca//Al exhibits an exponential diode characteristics with a threshold voltage around 5 V (shown in FIG. 13b). The observation of bright blue EL proves the advantage of the semiconducting material such as GaN outside the silica surface. However, to achieve better stability, efficiency, and to make use of these nanocomposites for fabrication of polymer-based devices, the device structure needs to be optimized.

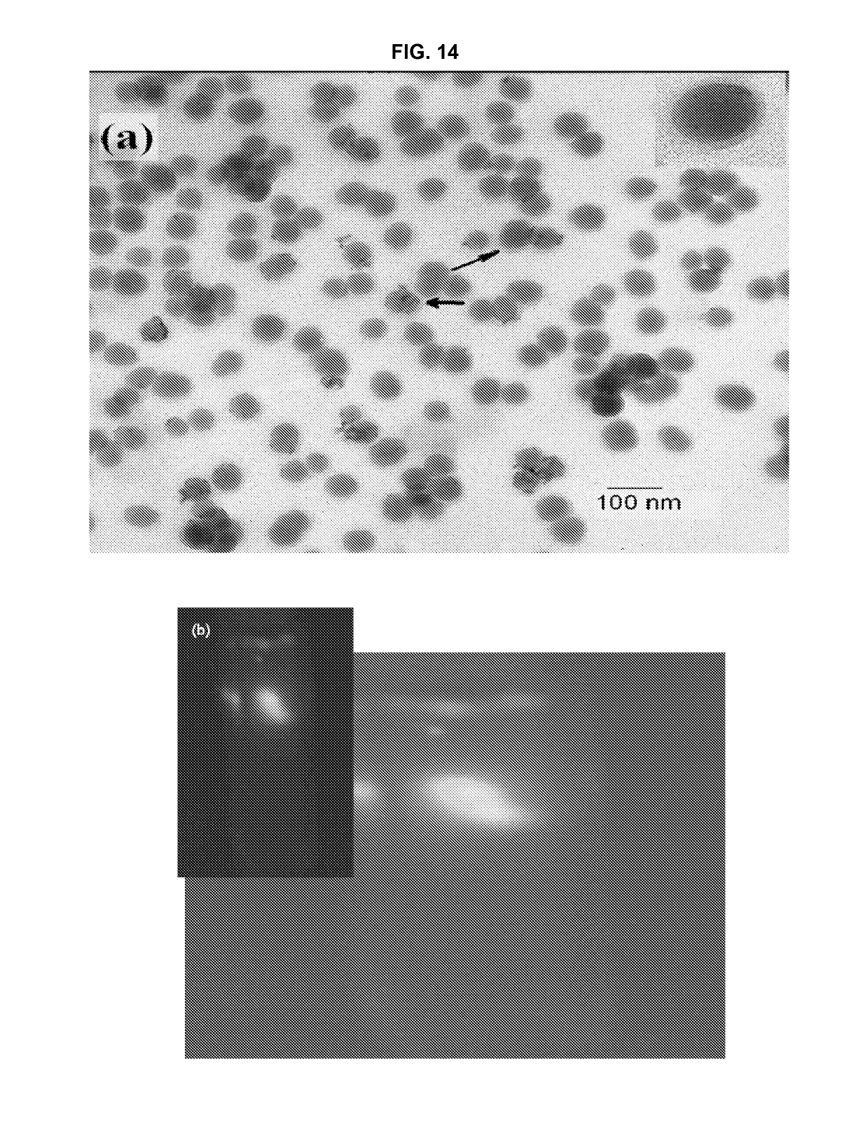

In order to show a feasible route, the Eu²⁺-doped GaN/SiO₂ nanocomposites were coated with a thin layer of polymethyl methacrylate. The TEM image shown in FIG. 14 confirms the formation of a thin layer of PMMA coating over the Eu²⁺-doped GaN/SiO₂ nanocomposites. The image also shows that the GaN nanoparticles attached to the silica surface were not affected by the PMMA coating. This was supported by the observation of a blue emission from the PMMA coated GaN/SiO₂ nanocomposites when excited at 285 nm. The emission spectrum collected from the Eu²⁻-doped GaN/SiO₂ nanocomposites matches exactly the emission spectrum of nanocomposites before PMMA coating indicating that the optical properties of the Eu²⁻-doped GaN/SiO₂ have not been affected by the thin polymer coating over them. A digital photograph of the blue emission from the Eu²⁺-doped GaN/SiO₂ dispersion in toluene is also shown in FIG. 14.

### P. Conclusions

The synthesis of Eu²⁺-doped GaN/SiO₂ nanocomposites has been demonstrated via a simple solid state reaction. The nanocomposites show a bright blue emission when excited in the ultraviolet region. The origin of the blue emission was attributed to the existence of europium ions in the +2 oxidation state. Thus, Eu²⁺ could be a potential alternative for other blue light-emitting Ln³⁺ ions such as Tm³⁺ or Dy³⁺. Various control experiments showed that the blue emission originates from the Eu²⁺ ions present in the nanocomposite matrix made with GaN and SiO₂, and it was most likely that the Eu²⁺ ions were located at the interface between GaN and silica. A bright blue electroluminescence was also observed from Eu^{2-+-doped GaN/SiO}₂ nanocomposites. In addition, the Eu²⁺-doped GaN/SiO₂ nanocomposites were coated with a thin layer of polymer to make them dispersible in organic medium. These polymer-coated Eu²⁺-doped GaN/SiO₂ nanocomposites were envisioned to have practical significance in the fabrication of polymer-based electronic devices.

### Example 5

### A. Chemicals

Tetraethyl orthosilicate, aqueous ammonium hydroxide (28-30%), indium nitrate (99.98%), urea, potassium bromide, and ethanol (99.9%) were used as received from Aldrich. The anhydrous ammonia gas (99.999%) used for the nitridation was purchased from Praxair. Milli-Q™ water with resistance greater than 18 mΩ was used.

### B. Preparation of Monodispersed Silica Nanoparticles

The silica nanoparticles with an average particle size of 50 nm were synthesized using a literature procedure. Briefly, 3.8 ml of tetraethyl orthosilicate was added to a mixture containing 114 ml of ethanol and 5.7 ml of ammonium hydroxide (28-30%) while vigorous stirring. Stirring was continued overnight, which resulted in the formation of silica nanoparticles with an average particle size of 50 nm. These silica particles were used as prepared, i.e. without isolation.

### C. Preparation of In₂O₃@SiO₂ Nanomaterial

In₂O₃@SiO₂ nanomaterial was prepared by adapting a procedure reported for Gd₂O₃:Eu@SiO₂. Briefly, 0.6 gram of urea dissolved in water was added to a flask containing 15 ml of 50 nm silica nanoparticles. To this mixture, a 0.2 M aqueous solution containing In(NO₃)₃.xH₂O (x=5, as provided by the supplier) was added drop wise. The resulting mixture was vigorously stirred at 85° C. for 3 hours. The excess urea was removed by centrifugation and the precipitate was dispersed in water 3 times. The resulting white product was dried in vacuum before heated to 600° C. for 9 hours.

### D. Preparation of InN@SiO₂ Nanomaterial

Approximately 100 mg of the In₂O₃@SiO₂ nanomaterials was taken in a quartz crucible and placed in an electric furnace (Lindberg HTF553222A with a CC58114PA controller). The furnace was heated to 700° C. at a rate of 5° C. per minute in an NH₃ atmosphere. The sample was left at the final temperature for 2 hours before it was cooled down to room temperature in NH₃ atmosphere. The ammonia flow was maintained at 100 SCCM (cubic centimeter per minute at STP). The formation of the InN was indicated by a color change of the sample from colorless to grayish black.

### E. Photoluminescence Measurements

Photoluminescence (PL) measurements were carried out using an Edinburgh Instruments' FLS 920 instrument with a 450 W Xe arc lamp and a red-sensitive Peltier element-cooled Hamamatsu R928 PMT. The measurement was done using a solid sample holder. A KBr pellet was prepared by mixing the sample and the KBr in a weight ratio 1:10 and placed in a solid sample holder. All spectra were recorded with 1 nm resolution and were corrected for the instrument response. The filters used were 320 nm and 435 nm for the collection of emission and the excitation spectra, respectively.

### F. X-Ray Powder Diffraction (XRD) Measurements

The XRD pattern of the InN@SiO₂ nanomaterial was collected using a Rigaku Miniflex X-ray diffractometer with a Cr K_{α} (30 kV, 15 mA) radiation source. The nanoparticle samples were gently crushed to break down big lumps and a thick paste was made using ethanol. This thick paste was evenly spread onto a clean quartz slide and the ethanol evaporated at 85° C. The powder diffraction patterns were collected over the 2θ range 20 to 140° with a scan speed and sampling width of 1°/min and 0.02°, respectively.

### G. Raman Spectroscopy

Raman spectra were collected by exciting the sample with 632.8 nm from a He—Ne Laser by Melles Griot. Roughly, 20 mg of the solid sample was placed on a clean glass slide and spread over the slide evenly using a spatula. The spectrum is an average of 3 scans with a 30 seconds collection time for each scan.

### H. Transmission Electron Microscopic Measurements

A Hitachi H-7000 tungsten filament up to 125 kV Transmission Electron Microscope was used to collect the TEM images. TEM specimens were prepared by dipping a copper grid (600 mesh), which is coated with an amorphous carbon film into the ethanol dispersion of the InN@SiO₂ nanomaterial and dried at room temperature.

### I. X-Ray Photo-Electron Spectroscopy

X-ray photoelectron spectra were collected using a Leybold Max200 spectrometer, using monochromatic Al K_{α} X-ray source (1486.6 eV). The pass energy for the survey and narrow scans were 192 and 48 eV, respectively. Photoelectrons were collected at 90° from the surface. All binding energies (BE) were recorded relative to the C1s peak (BE: 285.0 eV).

### J. Results and Discussion

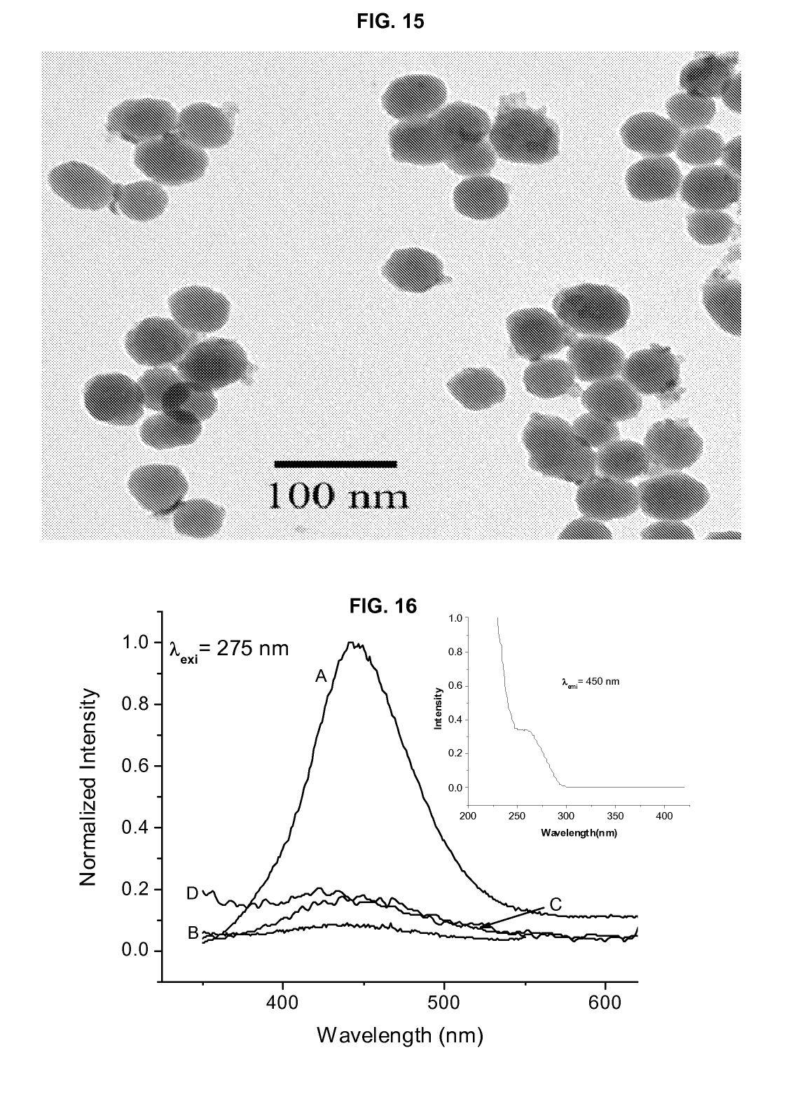

The InN@SiO₂ nanomaterials were prepared via a simple precipitation followed by a solid-state reaction. Briefly, an aqueous solution containing indium nitrate and urea was added drop wise to 50 nm spherical silica nanoparticles followed by heating at 85° C. for 3 hours. This produces an In-urea complex over the silica nanoparticles. This resulting white precipitate was washed 3 times with water to remove any excess urea and followed by drying under vacuum. Subsequently, the white powder was heated to 600° C. in air which resulted in a yellowish-white powder due to the formation of an In₂O₃ on silica. The yellowish-white powder was nitridated under nitrogen which results in the formation of a black material. The black color indicates the formation of the InN. To understand the structure of the black material TEM analysis was performed. The TEM image shown in FIG. 15 shows the formation of small nanostructures of InN that are attached to the surface of the silica particles. In order to confirm the formation of the InN we carried out an XRD analysis. The XRD pattern collected from InN@SiO₂ nanomaterial shows that the observed pattern corresponds well with that reported for crystalline InN. The broad diffraction peak at 20° (2θ) corresponds to the amorphous silica phase. Additionally, the formation of the InN was confirmed by Raman analysis. The room temperature Raman spectrum for InN@SiO₂ nanomaterial was conducted. The peak at wave number of about 590 cm⁻¹ is assigned to A₁ [longitudinal optical (LO)] phonon peak of InN. The characteristic Raman Si—O—Si bending vibration appearing at 430 cm⁻¹ is not clearly seen in the spectrum as it is overshadowed by the strong Raman band from InN.

### K. Optical Properties of InN@SiO₂

The photoluminescence (PL) spectrum collected from InN@SiO₂ nanomaterial displays a blue emission centered at 450 nm when excited in the UV region. This blue emission was easily seen by the naked eye. FIG. 16A shows the emission spectrum along with the excitation spectrum in the inset. The material has a strong absorption in the UV with a shoulder close to 275 nm and an onset at ˜300 nm. The emission peak is strongly blue-shifted compared to band gap emission (600-700 nm) reported for the InN nanomaterials.

As quantum confinement effects are not expected in this case, due to irregular shapes of the nanomaterials, various control experiments were performed to understand the origin of the blue emission. First, to verify whether the emission was coming from the indium nitride, InN material alone was prepared using a similar procedure. No emission was observed from this sample. Second, the silica particles alone were heated in NH₃ under identical conditions. Only a very weak emission was observed from the SiO₂ after nitridation (FIG. 16B). This weak emission could have come from carbon related impurities present in silica, which has been observed earlier. Thirdly, to confirm whether the emission was coming from In₂O₃ present in a very small amount (as In₂O₃ shows broad emission in the blue region due to oxygen deficiencies), and to understand the need for the nitridation, the precursor nanoparticles, i.e. In₂O₃@SiO₂ material, was heated at 700° C. in an argon atmosphere. The absence of any characteristic emission from this sample (FIG. 16C) indicates the importance of the presence of InN@SiO₂ in producing the blue emission. In order to confirm this, another control sample was made by mixing the In₂O₃ and silica particles together followed by nitridation under the same conditions used for the preparation of InN@SiO₂. The resulting mixture displays only a very weak emission (FIG. 16D), which highlights the importance of the InN growing on the surface of a SiO₂ nanostructure for the blue emission.

The above control experiments clearly verify the importance of both InN and silica in producing the blue emission from InN@SiO₂ nanomaterial. Moreover, the absence of any characteristic emission from the hybrid mixture (i.e. In₂O₃ and silica separately made and mixed together) after nitridation substantiates the importance of growing the In₂O₃ on the silica template (In₂O₃@SiO₂). This observation indicates that the interface between the InN and silica plays an important role in bringing the blue emission. Without being bound to theory, one possibility could be formation of a different material, such as In₂Si₂O₇, at the interface. Though In₂Si₂O₇ has characteristic luminescence it mostly falls in the ultraviolet region. Moreover, if it were In₂Si₂O₇, the precursor In₂O₃@SiO₂ would have exhibited the emission after heating but it only shows a weak emission (see above). The second possibility is the formation of In—O—N complex as observed by Liu et al., in their In—O—N nanospheres. The third possibility, which is closely related to the second, is the widening of the optical bandgap of InN with incorporation of oxygen. This is reported for the polycrystalline InN where the bandgap was increased from 1.55 eV to 2.27 eV with increasing oxygen concentration from 1% to 6%. These options are tentatively ruled out as no band gap emission was observed in InN alone, made under identical conditions. To get more insight, XPS analysis was performed on the InN@SiO₂ as well on the precursor nanomaterials. The results indicated that for the precursor In₂O₃@SiO₂, the expected ratios of 1:1.5 and 1:2 were observed for In:O and Si:O, respectively. However, InN@SiO₂ indicates an In/N ratio of 0.66 and Si/O ratio of 2. These results indicate that the material is richer in N than is strictly needed for InN.

Thus, the synthesis of a hybrid InN@SiO₂ has been demonstrated, which exhibit a blue emission when excited in the ultraviolet region. The structural characterization of the nanomaterials indicates formation of crystalline InN nanomaterial over the amorphous silica particles. Various control experiments support that the interface between the InN and silica plays an important role in the origin of the blue emission.

### Example 6

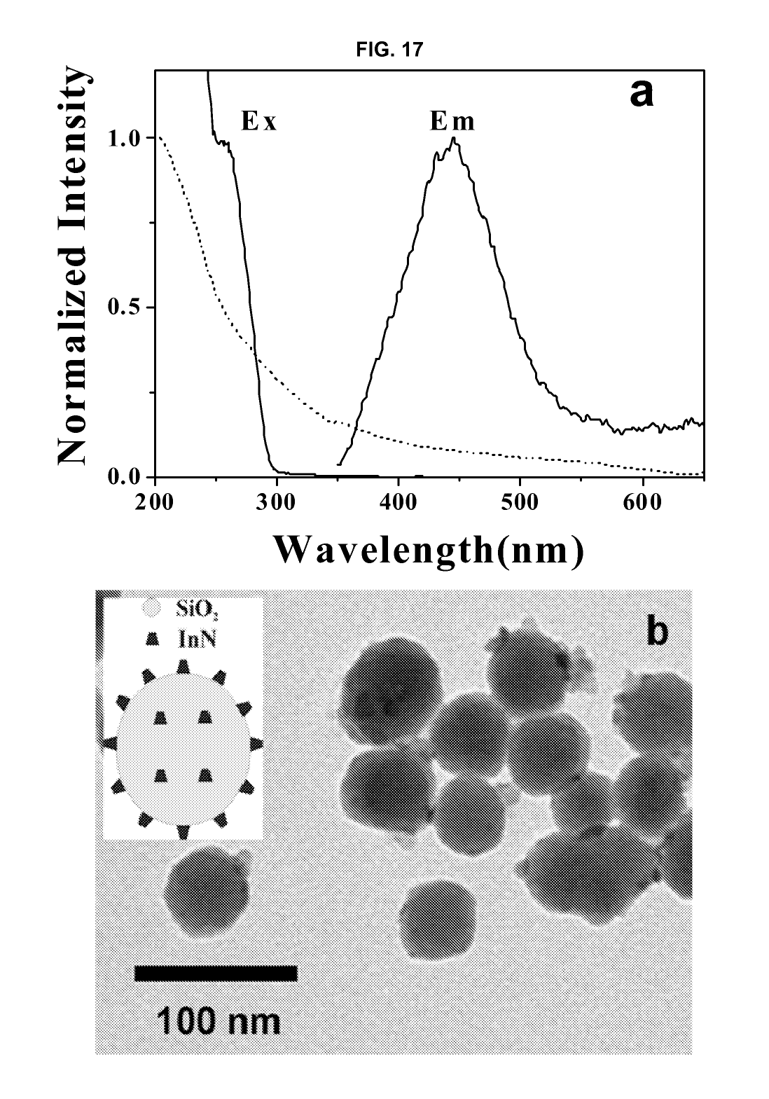

FIG. 17a shows the absorption and photoluminescence spectra of InN@SiO₂ nanoparticles measured at room temperature. These nanoparticles exhibit a blue emission centered at 445 nm when excited in the UV region, but no luminescence was observed corresponding to the most quoted band gap value, 1.89 eV (656 nm), or the recently reported band gap ˜0.70 eV (1771 nm). The blue luminescence was most likely not due to the quantum confinements in the InN nanostructure because of their irregular shapes observed on the surface of SiO₂ nanoparticles (FIG. 17b). A control sample such as InN—SiO₂ hybrid material prepared by directly mixing the same amount of In₂O₃ and pure SiO₂ nanoparticles and treated under identical nitridation conditions did not show the blue emission in the visible region.

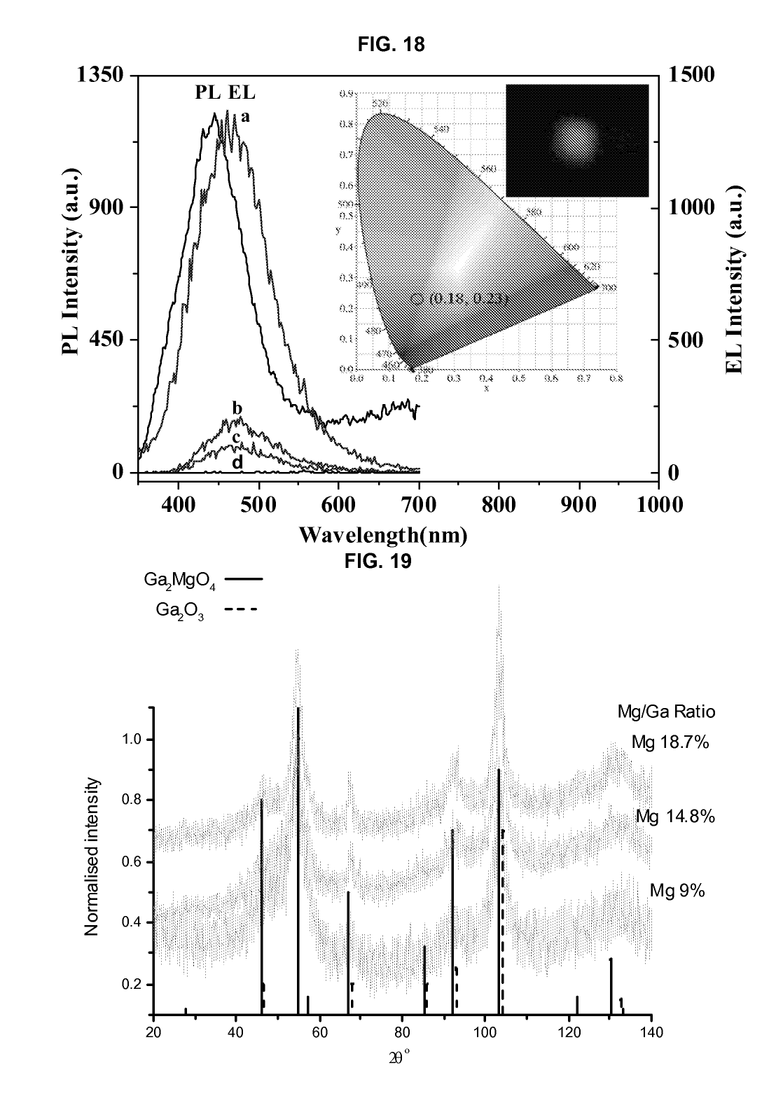

An EL device with a configuration of ITO//InN@SiO₂//Ca//Al was fabricated by simply spin-coating the nanoparticles onto an indium tin oxide (ITO) covered glass substrate. After drying, the metallic cathode (Ca protected by Al) was thermally deposited onto the emission layer with a shadow mask. The current-voltage (I-V) characteristic of the InN@SiO₂ EL device showed a clear diode-like behavior, with blue emission observed only in the forward bias, i.e., when a positive voltage was applied to the ITO electrode (FIG. 18). The log I/log V plot showed an ohmic behavior at low voltages (<4 V), following the I ∝ V^{1.4} relation, which indicates that current was limited by the InN@SiO2 layer. At higher voltages (>4 V), the I-V data was fit well to the trapped-charge-limited (TCL) current model, i.e., I ∝ V^{m} relation with m≈4. This suggests that the filling of the limited traps result in a rapid increase (power-law increase) in current at higher forward bias. QD-based LEDs and organic light-emitting devices have been reported to exhibit an I ∝ V m relation with variations in m values. Here, m was the signature of the charge condition mechanism and was related to the type of the emitting materials, the temperature, and the trap energy.

The EL device started to emit blue light, which was visible to the naked eye, at 9 V, when a dc voltage was applied to the device. As shown in FIG. 18, the intensity of EL emission increased with increased applied voltage with no change in emission wavelength. The EL occurs ˜460 nm, i.e., exhibiting ˜15 nm red-shift versus the PL peak at 445 nm. The red-shift of the EL, relative to the PL, was well known in nanocrystal-based EL. In the present technology, the reason for the red-shift of the EL could be explained by local Joule heating from the large current injection and relatively poor thermal conductivity of the emitting layer. Because there was no additional hole or electron transfer layers into which the recombination zone can extend, all the EL emission originated from InN@SiO₂ layer. This results in excellent color purity. Control devices fabricated using In₂O₃@SiO₂ or pure SiO₂ as emission layers did not show any blue EL (FIG. 18), substantiating that the blue EL occurs from the InN@SiO₂ nanomaterials. The calculated CIE (Commission International de l'Eclairage) coordinates for the EL spectrum in FIG. 16 were 0.18 and 0.23, which fall well within the blue region of 1931 CIE diagram. The calculated brightness of the blue emission was ˜0.3 cd/m² at 18 V with a luminous efficiency of 0.2 mcd/A at a current density of 150 mA/cm². The reason for the low brightness could be attributed to the poor charge injection efficiency on the inorganic nanomaterials surface. Though the observed brightness seems to be low, it was observed from an un-optimized device. Optimization of the devices could be achieved by the following ways (i) formation of a close packed monolayer for nanomaterials, (ii) combination with electron/hole transporting layers, and (iii) optimization of the device structures.

In conclusion, blue electroluminescence from InN@SiO₂ nanomaterials has been observed when the EL device was driven at a forward bias voltage. The control experiments and the comparison analysis of PL and EL showed that electron-hole recombination does occur in the InN@SiO₂ nanomaterials layer.

### Example 7

### A. Materials

Ga(NO₃)₃.xH₂O, Mg(NO₃)₂.6H₂O, Zn(NO₃)₂.6H₂O, tetraethylorthosilicate (TEOS), and glycine were purchased from Aldrich and used as received. The anhydrous ammonia gas (99.999%) used for the nitridation was purchased from Praxair. Milli-Q water with resistance greater than 18 MΩ was used in all examples.

### B. Preparation of the Oxide Precursors

The Mg²⁺- and Zn²⁺-doped gallium oxide precursors were prepared by the combustion method which has been reported elsewhere. Briefly, stoichiometric amounts of Ga(NO₃)₃.xH₂O (1.25 mmol, assuming x=8), Mg(NO₃)₂.6H₂O (0.20 mmol) or Zn(NO₃)₂.6H₂O (0.20 mmol), and glycine were dissolved in 25 ml of water by keeping a glycine-to-metal ion ratio of 1.2. The solution was slowly evaporated at 120° C., until a transparent residue was obtained. This was then heated to 220° C. The combustion reaction took place and a brownish-yellow colored product was obtained. The resulting solid was then heated in a flowing air at 650° C. for 5 hours to give white product consisting of Ga₂O₃, and Ga₂O₃:Mg²⁺/Zn²⁻.

### C. Preparation of Mg²⁺- and Zn²⁺-Doped GaN Nanoparticles

In a typical preparation, the oxide precursor material was put in a quartz crucible and placed inside a quartz furnace. Nitridation was performed in an ammonia atmosphere. The temperature of the furnace was increased to 950° C. at a rate of 5° C./minute. This temperature was maintained for 3 hours before it was cooled down to RT at the same rate in the NH₃ atmosphere. The NH₃ flow was maintained at 10 SCCM (cubic centimetre per minute at STP).

### D. X-Ray Powder Diffraction (XRD) Measurements

The XRD patterns of the oxide and nitride nanoparticles were collected using a Rigaku Miniflux X-ray diffractometer with a Cr K_{α} (30 kV, 15 mA) radiation source. The nanoparticle samples were gently crushed before being smeared on to a clean quartz slide. The powder diffraction patterns were collected over the 2θ range 20 to 140° C. with a scan speed and sampling width of 1°/minute and 0.02°, respectively.

### E. Transmission Electron Microscopy (TEM)

TEM was performed on the various nanoparticle and composite samples using a Hitachi H-7000 microscope operating at 75 kV. The microscope was equipped with a charge-coupled device (CCD)-camera. The samples were prepared by dispersing ˜1 mg of nanoparticles in 1 gram of ethanol. These nanoparticle dispersions were drop-casted on a formvar/carbon film supported on a 300 mesh copper grid (3 mm in diameter) and allowed to dry in air at room temperature.

### F. Raman Spectroscopic Measurements

Raman spectra were collected by exciting the sample with 632.8 nm He—Ne Laser by Melles Griot. The solid sample was evenly spread over a clean glass slide. Each spectrum is an average of 6 scans, each collected over 30 seconds.

### G. Photoluminescence (PL) Measurements

Room temperature PL measurements on the Mg²⁺- and Zn²⁺-doped GaN samples were performed using a 325 nm Omnichrome Series 74 He—Cd Laser by Melles Griot. The laser beam was focused on the Mg²⁺-/Zn²⁺-doped GaN particles through the microscope. A SpectroPro-500 monochromator by Acton Research Corporation was used to scan the PL signal in the visible range (350 nm-700 nm). The signal was amplified by a differential preamplifier and then acquired by the computer.

### H. Energy Dispersive X-Ray Spectroscopy

Energy dispersive X-ray spectroscopy was done using a Hitachi S-3500N scanning electron microscope, operated at 20 kV and a resolution of 102 eV. Dry powdered samples were attached to the substrate using a double-sided carbon tape, and mounted onto the sample holder. Each reported value is the result of three measurements.

### I. Results and Discussion

The Mg²⁺- and Zn²⁺-doped GaN nanoparticles were prepared by a solid state reaction. These nanoparticles were prepared by the nitridation of their corresponding oxides, which were produced by the glycine combustion method to yield small nanoparticles typically in the size range 5 to 10 nm. Three series of samples have been prepared, in which the percentage ratio X/Ga (X═Mg, Zn) in the initial mixture was 3%, 7.5%, and 15%.

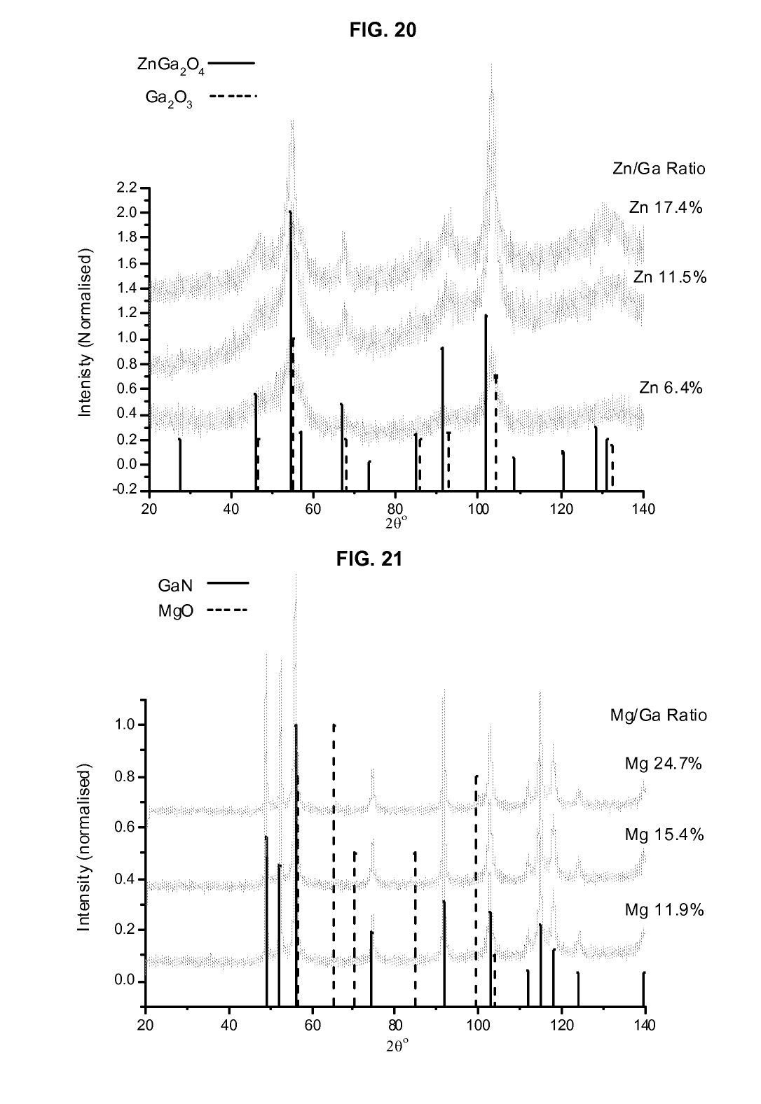

For preliminary work on the synthesis and characterization of the Mg²⁻-doped GaN nanoparticles the XRD patterns of the intermediate products were refined only taking into account the presence of Ga₂MgO₄. A careful re-examination of the XRD furnished more insight on the formation of the intermediate products and the presence of Ga₂O₃ cannot be excluded. Both Ga₂MgO₄ and Ga₂ZnO₄ present diffraction patterns which are very similar to Ga₂O₃ and the broadness of the peaks in nano-crystalline samples might as well hide both contributions. As shown in FIGS. 19 and 20, the reference patterns for Ga₂MgO₄ and Ga₂ZnO₄ should present some peaks at high and low 2θ that are not close to any other peak of Ga₂O₃ and should be indicative of the presence of the double oxides (122°, 130° for Ga₂MgO₄, and 27°, 109°, 120°, 129° for Ga₂ZnO₄). However, the intensity of these peaks is extremely low or absent; therefore, Ga₂MgO₄ and Ga₂ZnO₄, if present, might constitute a very small contribution. It is thus more reasonable to infer that Mg²⁺ and Zn²⁺ are already in the Ga₂O₃ as dopants.

The relative amounts of Mg²⁺ and Zn²⁺ in the intermediate products is evident from the EDX analyses, which are reported in Table 1, below.

TABLE 1
X/Ga molar ratios (X = Mg or Zn) are reported for each
sample. They are weighted in the initial mixture (second row)
and measured with EDXs in the intermediate oxides (third row),
and in the doped nitrides (fourth row).

| Dopant X | Mg | Mg | Mg | Zn | Zn | Zn |
|---|---|---|---|---|---|---|
| Initial mixture | 3% | 7.5% | 15% | 3% | 7.5% | 15% |
| Intermediate | 9% | 14.8% | 18.7% | 6.4% | 11.5% | 17.4% |
| oxides | | | | | | |
| Doped nitrides | 11.9% | 15.4% | 24.7% | 4.3% | 2.9% | 2.6% |

The concentrations in the intermediate oxides are proportional to the amounts in the initial mixture, but they are a little bit higher, especially for the lower concentrations. This occurs because part of the gallium does not reach the intermediate products. The relative amount of X also decreases with the concentrations; this suggests that the loss of gallium is proportional to the amount of gallium that does not form the intermediate product.

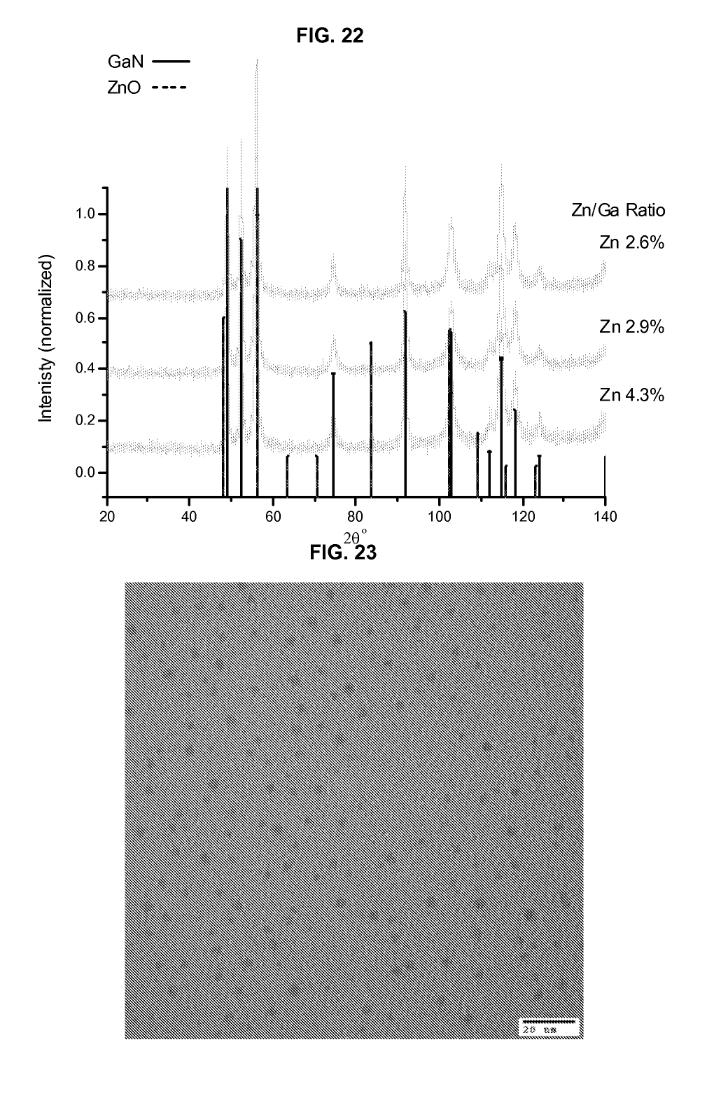

Despite the possibility of having various intermediate products, the second step of the reaction leads without any doubt to the formation of Mg²⁺- or Zn²⁺-doped GaN, as the XRD patterns in FIGS. 21 and 22 clearly show the wurtzite structure of GaN. In the case of Mg²⁺-doped GaN, FIG. 21 shows an emerging peak at 65° and a shoulder at 99°, which increase with the concentration, denoting the increasing presence of some MgO. In FIG. 22 no observable presence of ZnO can be discerned. The reason for this could be the low boiling point of zinc (907.0° C.), which is reached during the nitridation. Hence zinc may be lost during the nitridation. The nitridation is done in a reducing environment (i.e. NH₃), so the reduction of Zn²⁺ to Zn metal is possible. It could also be so small in size or amorphous and thus unobservable with XRD. On the other hand, the boiling point of magnesium is 1107.0° C., which makes magnesium evaporation occur more slowly. The doping levels of Zn²⁺ and Mg²⁻ in the GaN nanoparticles can again be appreciated with the EDX data. Table 1 shows the relative percentage amounts of dopants with respect to gallium. The concentration of dopants is higher in the case of the samples with magnesium. For the zinc doped samples the concentration of the dopant in GaN is also inversely proportional to the amount of Zn(NO₃)₂.6H₂O in the initial reaction mixture. The reason for this could be the low boiling point of zinc (907.0° C.), which is reached during the nitridation. Hence zinc may be lost during the nitridation. The nitridation is done in a reducing environment (i.e. NH₃), so the reduction of Zn²⁺ to Zn metal is possible. On the other hand, the boiling point of magnesium is 1107.0° C., which makes this evaporation more slowly. The size of the nanoparticles is between 2 and 5 nm in all cases, it was determined by TEM, and is reported for each sample in Table 2, below.

TABLE 2
Second row: concentration of the dopants in the GaN nanoparticles.
Third row: size of the doped nitrides nanoparticles estimated from
the TEM images.

| Dopant X | Mg | Mg | Mg | Zn | Zn | Zn |
|---|---|---|---|---|---|---|
| Doped | 11.9% | 15.4% | 24.7% | 4.3% | 2.9% | 2.6% |
| nitrides | | | | | | |
| NPs size (nm) | 4.0 ± 2.6 | 3.5 ± 2.2 | 3.8 ± 0.8 | 3.3 ± 0.7 | 2.9 ± 0.9 | 2.7 ± 1.1 |

FIG. 23 shows a representative TEM image of one of the samples (2.9% doped Zn:GaN) and shows roughly spherical particles (see supporting information for TEM images of the other samples).

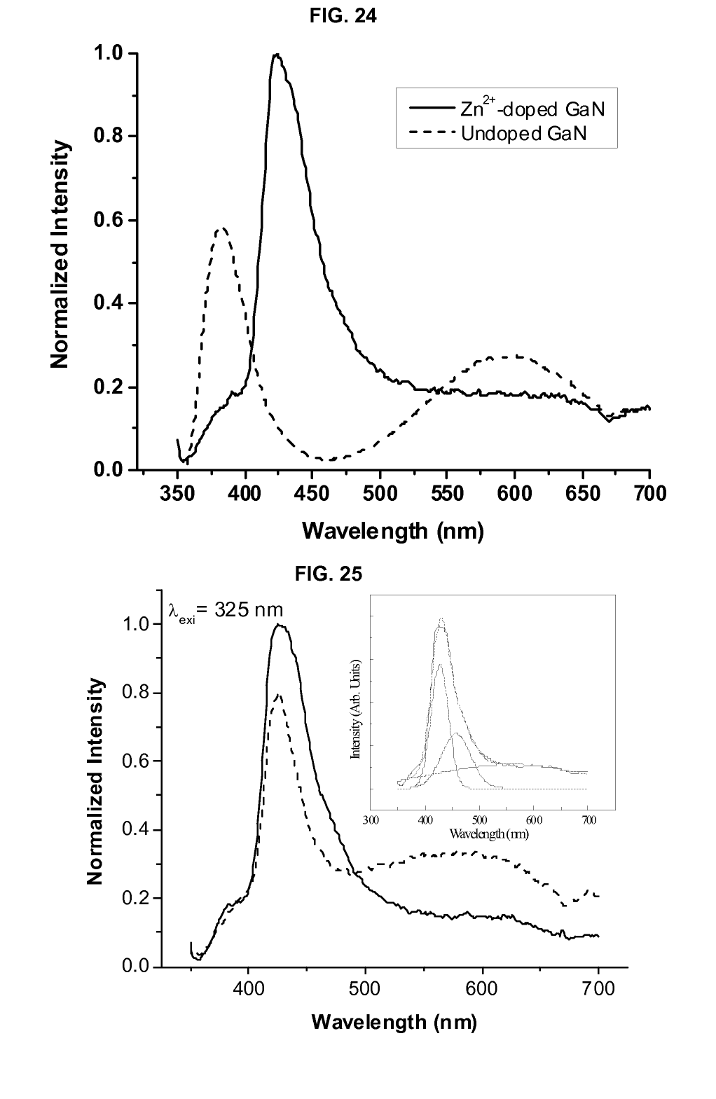

Both Mg²⁺- and Zn²⁺-doped GaN nanoparticles exhibit bright blue emission at 425 nm when excited at 325 nm. This PL peak position is red-shifted by roughly 50 nm with respect to the undoped GaN nanoparticles. For example, FIG. 24 displays the emission spectra of 3% Zn²⁺-doped GaN nanoparticles and the undoped GaN nanoparticles. The shift in the emission is attributed to the doping of Zn²⁺ ions into the GaN matrix. However the shoulder at 395 nm in the spectrum of the sample denotes the presence of some residual undoped GaN. Similar blue emission has been observed and well-studied for the Mg²⁺- and Zn²⁺-doped GaN in films. These peaks are attributed to donor-acceptor pair recombination, preferentially from the conduction band to the shallow acceptor states (ca. 0.5 eV above the valence band) created by the incorporation of Mg²⁺ or Zn²⁺. Upon excitation in the UV region, most of the electrons from the conduction band non-radiatively relax to the defect level from where the PL originates. In addition to these peaks there is also a broad band observed around 600 nm, which is more pronounced in the case of undoped GaN nanoparticles compared to Zn²⁺-doped nanoparticles. The origin of this peak is still an unresolved problem in the GaN literature. This is normally denoted as the “yellow emission” and assigned to the certain type of defects in the GaN lattice.

Size dependent effects between different samples likely can be excluded, because the size of the nanoparticles observed with TEM is very similar for all the samples (Table 2). The size distribution may cause inhomogeneous broadening of the PL bands. FIG. 25 shows the PL spectra of the 3% Mg²⁺-doped GaN nanoparticles with the corresponding Zn²⁻-doped nanoparticles. Though the main PL peak for both Mg²⁺ and Zn²⁺-doped GaN nanoparticles appears at 425 nm, at a closer look, the emission spectrum of the Zn²⁺-doped GaN nanoparticles show an additional shoulder towards longer wavelength. This is clear from FIG. 25. Moreover, the Gaussian fitting of the emission peaks of Zn²⁻-doped nanoparticles shows two peaks with peak maximum centering at 427 and 458 nm, respectively (Inset of FIG. 25). The multiple peaks could be attributed to the presence of additional defect states created by the incorporation of zinc ions into the GaN matrix. It has been discussed in the literature that Zn²⁺ ions not only occupy the gallium site (Zn_{Ga}) but also zinc at nitrogen sites (Zn_{N}, Zn⁻_{N} or Zn²⁻_{N}). The latter scenario leads to additional luminescence bands at lower energies. The sharp emission at 427 nm can arise from the Zn_{Ga} whereas the origin of the one near 458 nm is attributed to the zinc ions at the nitrogen vacancy. This difference in the luminescence is possibly due to the different reactivity (solubility) of the Mg²⁺ and Zn²⁻ ions during the growth of GaN nanoparticles.

The difference in the optical properties between the Mg²⁺- and Zn²⁺-doped GaN nanoparticles is not limited to the difference in the shape of the PL peak but also the defect-related yellow emission as well as the observed PL trend for different doping levels (see below). The observed yellow emission near 580 nm is more pronounced in the Mg²⁺-doped GaN compared to Zn²⁺-doped nanoparticles (FIG. 25). Similar results have been observed for Mg²⁺- and Zn²⁺-doped GaN crystals. As stated above, though the origin of this yellow emission has been debated for long time, it is understood that C, N, O, H, etc. play an important role in the creation of certain type of defects. It is not only limited to these elements but other elements as well, and the preparation condition might also play a role. Recently, Kudrawiec et al. have demonstrated that the yellow emission is associated with surface-related defects. This was studied using Eu³⁺-doped GaN powders, where they observed that the intensity of the yellow emission is dominant in nanosized grains compared to the micrometer-sized grains. Considering the above observation, Mg²⁺ doping creates more defects on the GaN lattice compared to the Zn²⁺-doped GaN nanoparticles, most likely closer to the surface of the nanoparticles. The presence of more lattice defects in Mg²⁺-doped GaN nanoparticles is substantiated by the Raman analysis (see below).

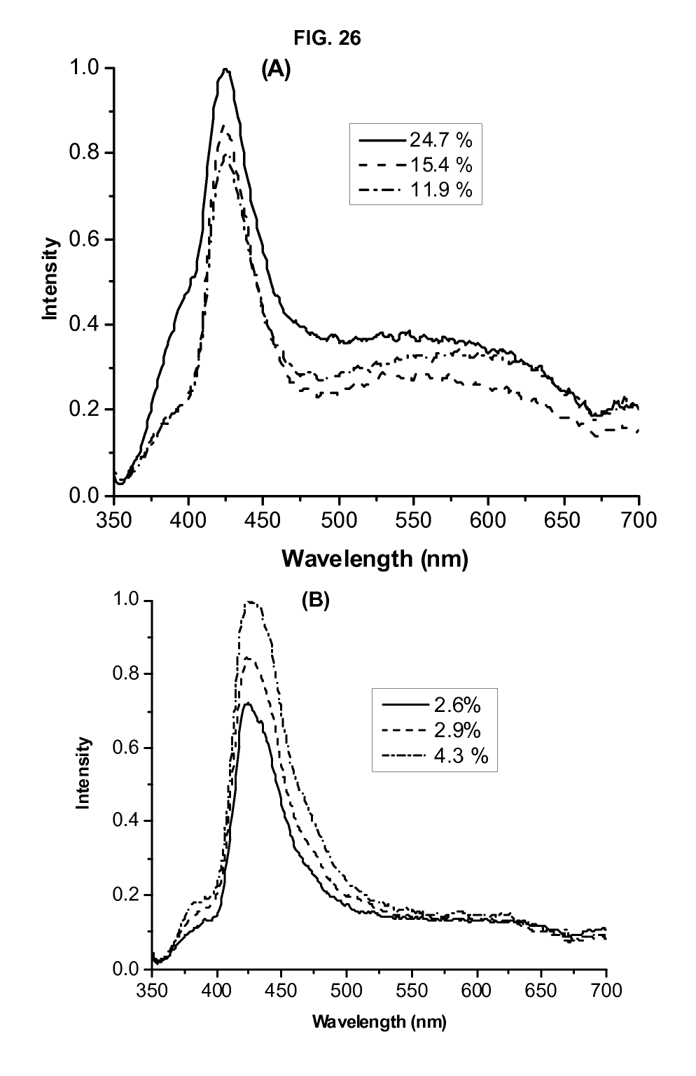

FIG. 26 shows the PL trends observed in Mg²⁺- and Zn²⁺-doped GaN samples with different doping concentrations. In both cases the intensity is proportional to the measured concentration; however, due to intrinsic errors in the measurements the EDX data should be considered only to identify a trend, rather than an absolute correspondence between concentration and PL intensity.

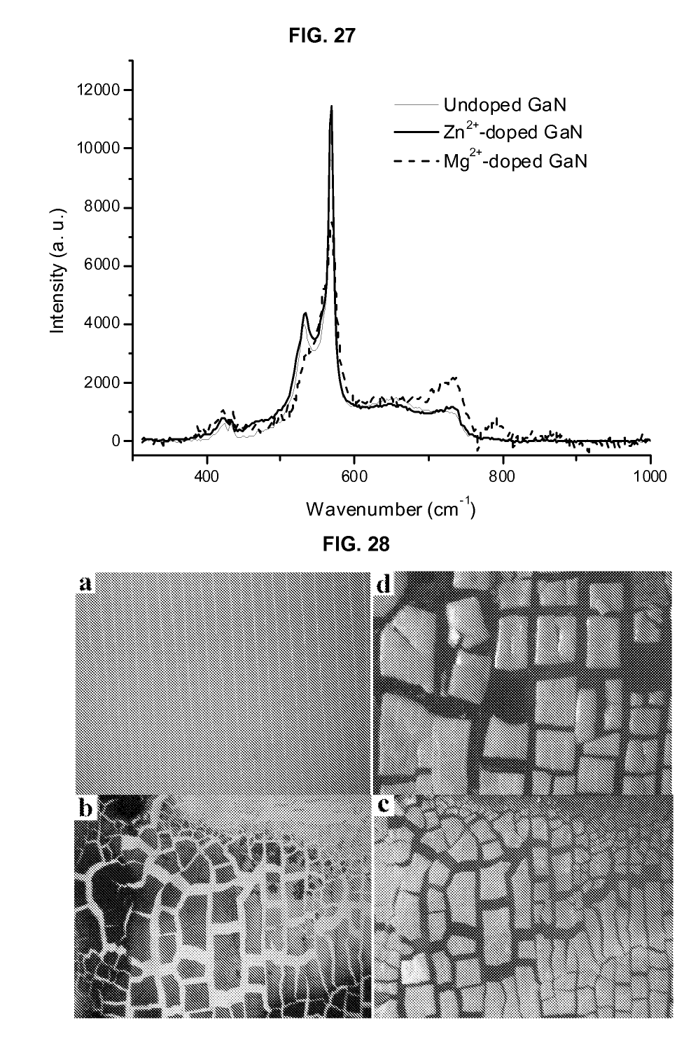

The insertion into the lattice of ions with different size and charge in the place of gallium, produces structural modifications of the host site and at the level of the second sphere of coordination due to charge compensation mechanisms. Therefore, in order to obtain more insight on the structural characteristics, we performed Raman analyses. The Raman spectra collected from the Mg²⁺- and Zn²⁺-doped and undoped GaN nanoparticles are shown in FIG. 27. For comparison, the spectrum of the undoped GaN nanoparticles is also displayed. All three spectra display a strong peak at 570 cm⁻¹ which is the characteristic E₂ phonon frequency of the host GaN. Additionally, the spectra show a few other weak bands at 530, 650 and 727 cm⁻¹. The peak at 530 cm⁻¹ is assigned to the A₁ optical modes and the latter two bands are attributed to the disorder-activated Raman scattering. These disorder-activated bands are originally Raman inactive modes and their appearance is ascribed to the distortion in the lattice structure. As is clear from the Raman spectra the peak at 727 cm⁻¹ is more intense in the Mg²⁺-doped GaN compared to the Zn²⁻-doped samples and it is quite weak in the undoped GaN nanoparticles. This clearly implies that there is more lattice rearrangement in the case of Mg²⁺-doped GaN compared to Zn²⁺- and undoped GaN samples.

### J. Conclusions

The structural and optical characteristics of GaN nanoparticles have been studied by doping different amounts of Mg²⁺ and Zn²⁺ ions. Both nanoparticles exhibit a blue emission. The distortion of the lattice due to the incorporation of these ions into GaN host matrix is confirmed by the presence of additional modes present in the Raman spectra.

Overall, the optical characteristics of both Mg²⁺- and Zn²⁺-doped GaN nanoparticles display high reproducibility, which is very much essential to envision the application of these nanoparticles for the development of future optoelectronic devices.

### Example 8

### A. Chemicals

All the chemicals were used as received from Aldrich: tetraethyl orthosilicate, gallium nitrate (99.98%), europium nitrate (99.98%). The anhydrous ammonia gas (99.999%) used for the nitradation was purchased from Praxiar. Milli-Q water with resistance greater than 18 MΩ was used in all experiments.

### B. Sample Preparation

The samples were prepared starting from the vertical deposition of polystyrene beads (PBs) (Bangs Laboratories) of different sizes, depending on the desired position of the SB. A new quartz slide (Chemglass CGQ-06040-10) previously etched overnight with chromic acid, was vertically soaked in a 0.3 weight % water dispersion of PBs, and heated at 60° C. for about 14 hours, until complete evaporation. The self-assembly of the spheres into a face centred cubic (fcc) lattice led to the formation of an opal. These opals acted as templates for the preparation of the inverse opal sample: they were infiltrated with a dispersion of 50 nm silica nanoparticles formed by the hydrolysis and condensation of tetraethyl orthosilicate in 1:5 ethanol solution. The pH was set at 1 with the addition of few drops of 1N HCl. On the surface of these silica colloids a thin shell of Eu³⁻ doped Ga₂O₃ was grown infiltrating the opal with Eu(NO₃)₃ and Ga(NO₃)₃ in a 1:10 ratio in water solution, the concentration of Eu(NO₃)₃ was 1 mM, while the concentration of Ga(NO₃)₃ was 10 mM. For the infiltration the quartz slide was horizontally immersed two times, for three minutes each time, in a 1:5, by volume, mixture of the nitrates solution and the silica nanoparticles dispersion. The homogenization of the mixture provides a simultaneous infiltration of the silica and the dopants and ensures the homogeneity of the distribution of the europium all over the structure. The formation of Ga₂O₃, the nitridation to GaN and the reduction of Eu³⁺ to Eu²⁺ was performed in an electric furnace (Lindberg) in a single thermal cycle. The temperature was raised to 650° C. in 6 hours, dwelled there for 2 hours and raised further to 950° C. in 6 hours. At this point NH₃ was fluxed at a rate of 10 SCCM (cubic centimeter per minute at STP) keeping the temperature for 2 hours. After that, the temperature was decreased to room temperature in 6 hours. During the first step at 650° C. the nitrates are transformed into oxides. During the second step the oxides are transformed into nitrides and the Eu³⁺ is reduced to Eu²⁺. This process leads to the formation of GaN nanoparticles on the surface of the silica. In this case, the silica was not in the form of nano-particles, but instead was a solid inverse opaline structure. At the end, the inverse opaline structure has replaced the empty spaces of the direct opal and the polystyrene beads have been completely removed, leaving spherical voids filled with air.

The two references were grown from 300 and 540 nm PBs, respectively. Such references resemble the scattering properties of the sample but their stop bands cannot affect the photonic properties of the active ion. For the quantum yield (QY) measurements study, beside this reference, yet another control sample also is needed, which mimics the scattering characteristics of sample and reference at the excitation wavelength, but which doesn't contain an optical emitter or absorber. Such control sample was synthesized following the same procedure, but without inserting Eu³⁺ as a dopant. Both were tried without any dopant and using Y³⁺ as a dopant. The results did not change. All the samples, references, and control samples compared in this work were rigorously grown in the same batch and in the same thermal cycle. SEM measurements were performed with a Hitachi S35000N scanning electron microscope operating at 15 kV. All the samples and references were characterized by Energy Dispersive X-ray spectroscopy (EDX) using a Hitachi S-3500N scanning electron microscope, operated at 20 kV and a resolution of 102 eV. Dry powdered samples were attached to the substrate using a double-sided carbon tape, and mounted onto the sample holder. Each reported value is the result of three measurements in different positions. The standard deviation was calculated on the average

### C. Photoluminescence Measurements

Photoluminescence measurement were recorded with an ‘Edinburg Instruments’ FLS 920 fluorimeter. For all the measurements the detector employed was an R928P Hamamatsu PMT, and the resolution due to the slits' aperture was 1 nm. The emission spectra of Eu²⁺ were measured exciting with a 450 W Xe arc lamp. Transmission spectra were measured with the same fluorimeter in a 180° geometry obtained by driving the light out of the fluorimeter with two optical fibres and two objectives to focus the light in and out of the sample with two Olympus 10× objectives. The lifetimes of the same ion were collected exciting with the 355 nm harmonic line of a Quantel Nd:YAG nanosecond laser and collected with a multi channel scaling card, whose time resolution was 5 ns. The lifetime values were calculated as effective lifetimes by using the formula:

$$τ = \frac{{\int }_{0}^{∞} t \cdot I \cdot d t}{{\int }_{0}^{∞} I \cdot d t} \qquad Equation 5$$

where τ is the lifetime, t is the time and I the intensity. Each decay was considered until the intensity reaches 1% of the initial intensity. The color coordinates were determined from the Tristimulus values calculated by the integration of the spectra after the application of the color matching functions, which account for the human eye sensitivity. The absolute QY was determined using an integrating sphere (Edinburgh instruments, 150 mm in diameter coated with barium sulfate). All the samples and references were placed in a cuvette inside the integrating sphere. The geometry of the measurement was 90° and a baffle was placed beside the sample on the emission monochromator side, in order to avoid that light directly scattered from the sample could be collected without bouncing on the walls of the sphere at least once. The reason is that a direct reflection could compromise the measurement because the samples could scatter light differently along different directions. The QY was calculated using the formula:

$$Q Y = \frac{\int {I}_{E} ( \overline{v} ) \cdot d \overline{v}}{\int {I}_{S - C} ( \overline{v} ) - \int {I}_{S - S} ( \overline{v} ) \cdot d \overline{v}} \qquad Equation 4$$

QY is the quantum yield, I_{E} is the emission intensity, I_{S-C} and I_{S-S} are the intensities of the light scattered from the control sample and from the sample, respectively and v̅ is the wave-number. Hence equation (4) expresses the ratio between the number of photons emitted (numerator) versus number of photons absorbed (denominator). The Electron Paramagnetic Resonance (EPR) spectrum was collected on a Brucker EMX instrument operating in the X-band (9.443 GHz) at 115 K.

### D. Results and Discussion

The growth method for the samples was optimized to maximize the quality of the opal. For instance, the concentration of the Polystyrene Beads (PBs) dispersion and the temperature of the oven, were adjusted to obtain a uniform coating of the quartz slide. In particular a slow evaporation (2 days) was preferable. The concentration was proportional to the thickness of the coating. A thick coating was generally uneven and not functional for optical transmission measurements. On the other hand a too thin coating was not uniform over the area of the slide and the quality of the face centred cubic (fcc) structure was low. The best compromise was provided by adjusting the concentration to just cover the slide completely. It is currently believed that effective thicknesses are from greater than 0 to at least about 10 micrometers, and more likely from about 1 to about 3 micrometers. Any attempt to increase the thickness decreased the quality of the structure, producing a wavy profile of the layer and a thickness step at about half of the slide's height due to a natural temperature oscillation and a sudden concentration increase.

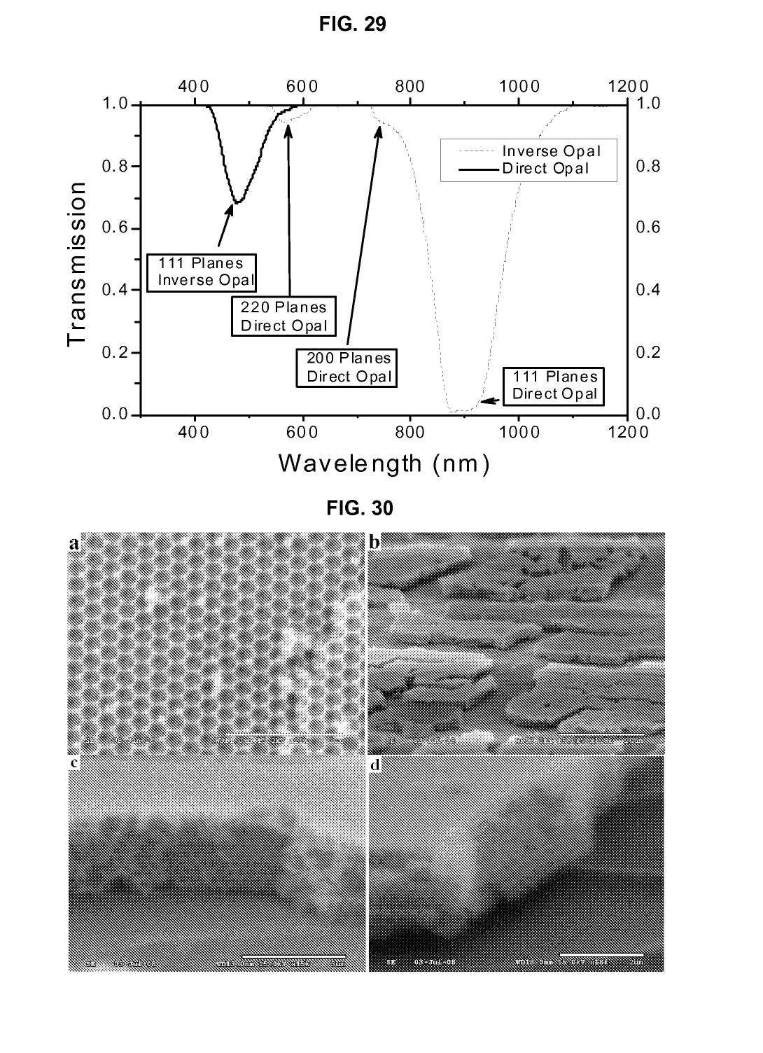

The quality of the opal also was influenced by the size of the beads: the smaller the beads, the easier it was to get a good quality structure. In particular it was fairly easy to obtain good quality opals with PBs smaller than 800 nm. If the size of the beads exceeded 900 nm the structure of the opal and the intensity of the SB decreased sensitively. FIG. 28a is a picture of an opal made from 400 nm PBs taken from an optical microscope on a 10× magnification, some longitudinal lines are observed on the layer, but the quality of the fcc structure is confirmed by the intensity of the stop band in the transmission spectrum measured perpendicular to the 111 planes of the lattice (FIG. 29, dotted line). The barycentre of the stop band in the spectrum matches the expected value calculated from equation.

$$λ = \frac{2 Sa}{m \sqrt{{h}^{2} + {k}^{2} + {l}^{2}}} [ φ {n}_{1} + ( 1 - φ ) {n}_{2} ] \qquad Equation 2$$

Where λ is the wavelength, S is a shrinkage factor, which takes into accounts the eventual shrinkage that a structure undergoes during its formation (vide infra), a is the cell's parameter, m is the order of Bragg's diffraction, n₁ and n₂ are the refractive indexes of the materials constituting the structure, and φ is the volume fraction of one of them, the other being the complementary (1−φ). Other stop bands corresponding to the 200, 220 and 311 series of planes are much less intense and negligible for our purposes.

For preparing the inverse opals the number and duration of each immersion was optimized at three minutes after many attempts, in order to have the most copious infiltration and the lowest possible damage to the lattice. Infiltration was driven by capillary forces in the convex structure and it was particularly effective as proved by the result shown in FIG. 30a. A constant 2 μm thickness of the sample can be appreciated from the Scanning Electron Microscopy (SEM) images in FIGS. 30b, c, d, where the number of layers can be counted at the extremities of the sample and in the middle (FIGS. 30a and 30b respectively). These figures also confirm the quality of the infiltration, which doesn't lead to any accumulation of silica on top of the inverse opal structure. The SEM images are slightly hazy because of some charging during the measurements.

The opalescent effect on the coloration of these samples is very strong. In the regions where they are not damaged they assume the color corresponding to the position of the stop band, when the light incides from the same direction of the observer, and the complementary color of the stop band, when the light comes from the opposite direction of the observation. FIG. 28b-d shows the intensity of the effect. Obviously the infiltration of the opal damaged the coatings a bit: in some parts it came off completely, and generally it was fragmented in “small islands” of roughly 0.1×0.2 mm. The reduced intensity of the stop band of the inverse opals observed in the transmission spectra is thus due to this fragmentation combined with the size of the beam (˜0.2 mm) used in the measurements. The transmittance of 70% observed in FIG. 29, is hence an average transmittance over the whole irradiated area of the slide, and therefore an underestimation of the real effect in these materials, due to the fact that some light is not passing through the sample. The shift in the position of the stop band passing from the opal to the inverse opal, according to equation (2), is mainly due to a shrinkage occurring during the thermal cycle. The voids are normally between 30 and 40% smaller than the PBs employed. Factor S in equation (2) takes into account this shrinkage.

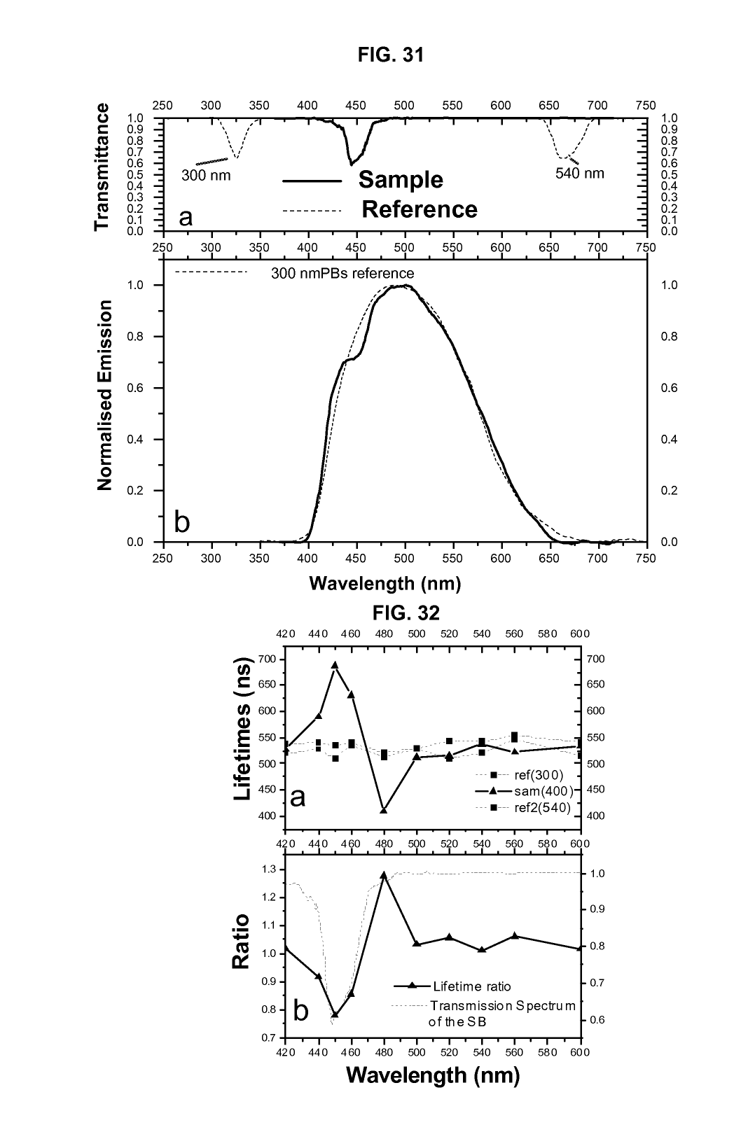

For this example, two references were needed: one to check the effect of the stop band on the Eu²⁺ emission; and one to be used as control sample for the determination of the absolute QY. The best one to study the effect of the stop band is an inverse opal grown in the same way as the sample, doped with Eu²⁺, but starting from a different size of PBs in order to have the stop band outside the Eu²⁺ emission. FIG. 31a shows the transmission spectra of the inverse opals compared with its two references. The sample grown from 400 nm PBs and the references grown from 300 and 540 PBs present stop bands at 477, 325, 662 nm, respectively. The resulting shrinkage is 40% for the sample and the 325 nm reference and 35% for the 662 nm reference. The shrinkage seems to be higher for smaller particles/holes; this trend was confirmed in all the samples measured.

Each sample and reference underwent elemental analysis by Energy Dispersive X-ray Spectroscopy (EDX). The ratio between europium and gallium was 9.4±0.7%, 10.3±0.8 and 9.8±0.7 in the sample, the reference grown from 300 nm PBs, and the one grown from 540 nm PBs, respectively. The amount of gallium with respect to silica was about 10%. These ratios are very close to the ratios used in the experiments.

The clearest evidence of the presence of Eu²⁺ in the sample comes from the broad and intense emission corresponding to the de-excitation of the t2g level of the 4f65d configuration to the ground level 8S7/2. This band is centered at around 500 nm, but its position changes sensitively changing the NH₃ flux during the nitridation. As a result, whenever samples of different size and different position of stop band are compared, these samples have been grown together undergoing the infiltrations in the same Petri dish and the same thermal cycle. Otherwise, differences could be due to slightly different pressures of NH₃ in the cylinder from one day to another, etc.

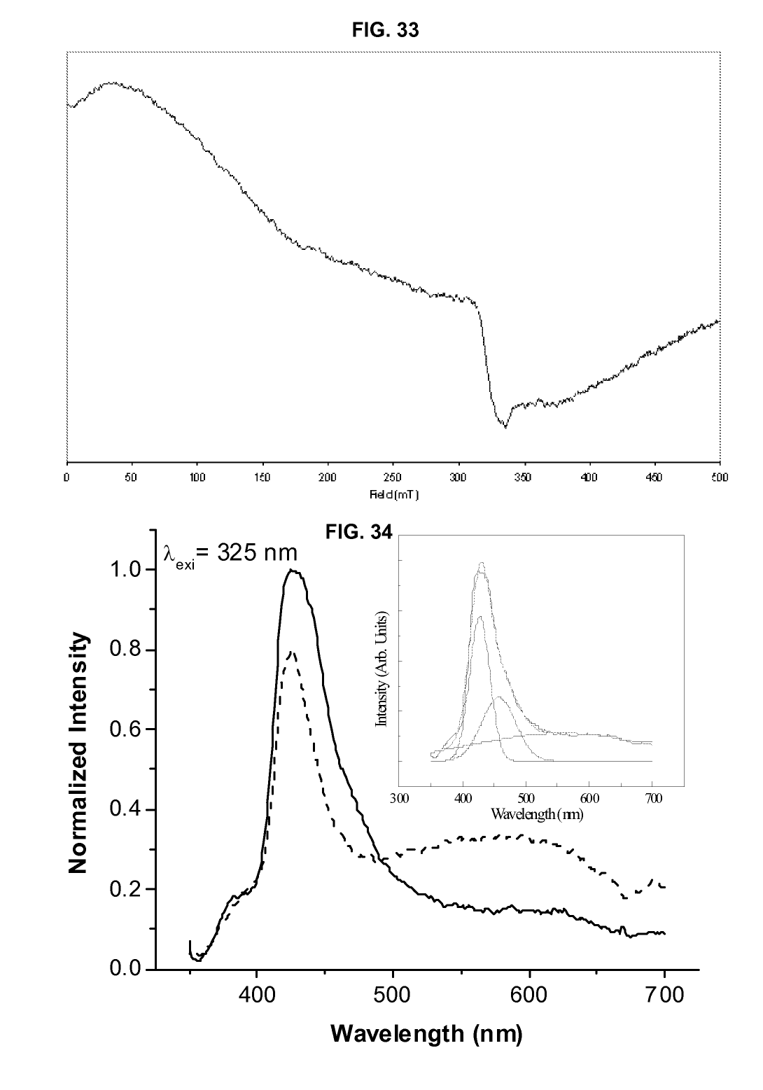

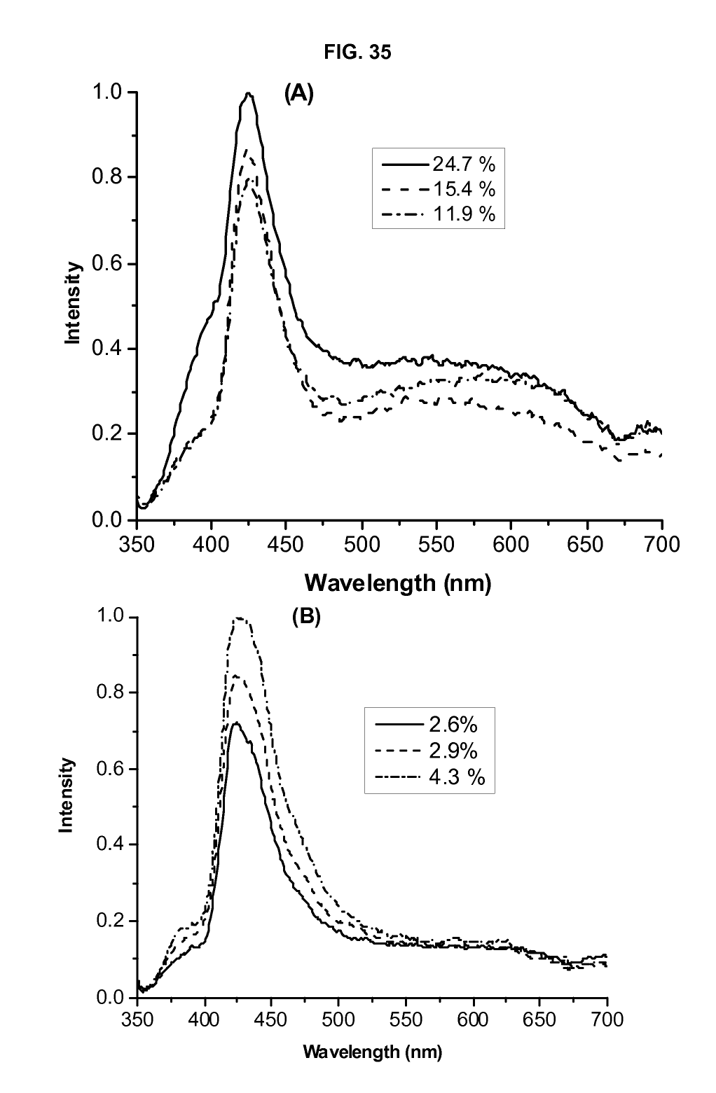

Another confirmation of the presence of the Eu²⁺ came from the Electron Paramagnetic Resonance (EPR) measurements (FIG. 33). The key feature is the ‘step’ that occurs between 320-340 mT. A step that occurs between 320 and 340 mT is typical of Eu²⁺, and its broadness is due the random orientation of the sample. The presence of the stop band was readily observed in transmission spectra, but in order to be able to observe it in emission the quality of the structure had to be refined. Part of the reason is due to the angle of measurement: in transmission spectroscopy the geometry of the measure is 180° and perpendicular to the 111 series of lattice planes, which is the direction in which the effect of the stop band is more intense. On the other hand, in emission spectroscopy the geometry of the measure was 90°, and the angular information was lost because a big portion of the emitted light was collected by the lens on the excident beam. For this reason, the stop band seen in emission is just an average effect over several different angles. FIG. 31b clearly shows the presence of the stop band as a dent at about 447 nm. The position of the stop band is reproducible in different samples because it depends on the size of the initial polystyrene beads. On the other hand the position of the emission maximum changes from growth to growth because it depends on the ammonia flux. In each example, the ammonia flows for more than 8 hours and small uncontrollable differences in the intensity of the flux from one example to the other lead to a different position of the emission maximum of Eu²⁺, resulting in different relative position with respect to the stop band. Attempts were made to optimize the characteristics of the sample having the stop band on the long energy side of the emission maximum; nevertheless, the best sample that was obtained presented the stop band on the high energy side. This was probably due to the fact that the most intense stop band is obtained starting from small beads.

The emission of the reference grown from 300 nm PBs is superimposed on the same graph, the emission of the reference grown from 540 nm PBs is not reported because is essentially similar to this one. The parallelism with FIG. 31a on top confirms that the stop bands on the references are outside the Eu²⁺ emission band and, as expected, they do not affect its density of states. In order to facilitate the comparisons between the positions of the bands' maxima, the spectra have been normalized. Therefore, the relative intensities cannot be compared, but just the shape of the spectra. The original intensities before normalization couldn't be compared either, because the amount of material excited in different samples is not necessarily the same. In the literature a number of papers can be found dealing with the orientational redistribution of light by photonic crystals. However, it is hard to find clear evidence of the redistribution in wavelength, which is however expected from theory. The shift in the emission maximum from 487 nm to 496 nm, shown in FIG. 31b with respect to the samples with the stop band outside of the Eu²⁺ emission, confirms this expectation. Another confirmation of this shift comes from the color coordinates calculated from the emission spectra of the sample (x=0.242, y=0.371) and the 300 nm (x=0.238, y=0.367) reference. Even more interesting is the confirmation coming from the QY measurements where the QY measured for the sample and for the references are 5.13±0.2% and 4.99±0.2%, respectively. The error on the QY value has been determined by repeating each measurement 10 times. These QYs are smaller than the ones reported in a previous work by Mahalingam et al. The emitter is Eu²⁺ albeit in a slightly different crystal field as evidenced by the different emission maxima. The constancy of the QY validates the theory that the wavelength redistribution is achieved without reducing the emission yield. Of course the angular redistribution is still present, but from examples where all the light is collected out of the sample inside the integrating sphere this effect is completely averaged. As a further confirmation of this intensity redistribution at different wavelengths, what is actually happening on the stop band was checked and on its edges by monitoring the lifetime, in order to have an actual picture of the reduction and increase of density of states. The decays of Eu²⁻ were not exactly mono-exponential, because of the non-homogeneity of the crystal field around the Eu²⁻. These experiments were carried out in a 90° geometry, the angular effect cannot be considered and the stop band is again an average over several directions. This is another non-negligible contribution to the broadness of the stop band. If the density of states decreases, according to equation (3) the lifetime becomes longer, on the other side if the density of states increases the lifetime becomes shorter.

W=2π|V_{fi}|²ρ(E_{fi}) Equation 3

With reference to equation 3, W is the transition rate, is the reduced Planck constant, V_{fi} is the matrix element of the potential that operates between the initial and final value, and ρ(E_{fi}) is the DOS at the energy of the transition.

FIG. 32a shows the behavior of the lifetimes at the wavelengths around the stop band. From the comparison with the same measurements on the references the lengthening within the range of the stop band is clearly seen. On the edge of the stop band the value at 480 nm definitely confirms the expected behaviour. FIG. 32b is a ratio between the lifetime of the reference grown from 300 nm PBs and the sample (the ratio with the other reference is not reported because it gives analogous values). When the ratio is close to one, the stop band has no effect on that particular wavelength. The increase and decrease of the ratio reflects the behavior of the density of states.

Employing photonic crystals in such a way it is possible to concentrate the emission intensity of an emitter on a desired range of wavelengths. By having a constant QY, the reduction in DOS in the range of the SB is accompanied by an increase of DOS and hence QY on the edge of the SB, which determines an increase of color purity of the emission. In the same way, by tuning the stop band on the low energy side of the emission band of an emitter, it would be possible to increase the efficiency of the device in the high energy range, which would be especially attractive in the ambit of the current quest for an intense emitter in the blue and at higher energies, extremely useful for a large number of applications, like data storage, high energy lasers, photodiodes, etc.

### E. Conclusion

In this example, a shift in the wavelength of the emission of an emitter by the action of a photonic crystal modifying its density of states was observed. Its effect resembles a smart filter capable of modifying the emission intensity without any loss of QY. This not only confirms the expectations coming from the theory, but it also opens the possibility to mold the intensity profile of an emitter. In particular, tuning the stop band on the long wavelength side with respect to the maximum of the emission, it is possible to increase the efficiency of a device on the blue side of the spectrum and at higher energy.

In view of the many possible embodiments to which the principles of the disclosed invention may be applied, it should be recognized that the illustrated embodiments are only preferred examples of the invention and should not be taken as limiting the scope of the invention. Rather, the scope of the invention is defined by the following claims. We therefore claim as our invention all that comes within the scope and spirit of these claims.

1. A method for the making a blue light emitting nanomaterial, comprising:
nitriding Group 13 metals to produce nitrided Group 13 metals; and
doping the nitrided Group 13 metals with a dopant having a plus 2 charge, thereby forming a doped blue light emitting nanomaterial.

2. The method according to claim 2 where the dopant having a plus 2 charge is Mg²⁺, Zn²⁺, Eu²⁺, or combinations thereof.

3. The method of claim 1 wherein the Group 13 metal is gallium.

4. The method of claim 1 where the Group 13 metal is indium.

5. The method of claim 2 wherein the dopant is Mg²⁺ or Zn²⁺.

6. The method of claim 1 where doping controls defect formation.

7. The method of claim 1 where the nanomaterials emit blue light with a maximum at about 410 nm to about 500 nm.

8. The method of claim 7 wherein the nanomaterials emit blue light with a maximum at about 420 nm to about 450 nm.

9. The method of claim 1 wherein the nanomaterials are nanocrystals.

10. The method of claim 1 further comprising coating the nanomaterials.

11. The method of claim 10 wherein the nanomaterials are coated with an organic phosphine oxide.

12. The method according to claim 11 where the organic phosphine oxide is a trialkylphosphine oxide.

13. The method according to claim 12 where the trialkylphosphine oxide is trioctylphosphine oxide.

14. The method according to claim 1 further comprising coupling the doped blue light emitting nanomaterial to a photonic crystal.

15. The method according to claim 14 where the photonic crystal is selected based on the position of the bandgap/stopband.

16. A method for making a blue light emitting nanomaterial, comprising:
preparing SiO₂ nanoparticles;
doping a Group 13 metal oxide with a dopant having a plus 2 charge, or a dopant that can be reduced to a plus 2 charged, to produce a doped nanomaterial;
coating the SiO₂ nanoparticles with the doped nanomaterial; and
nitriding the doped nanomaterial to produce a blue light emitting nanomaterial.

17. The method according to claim 16 where doping a Group 13 metal oxide comprises doping GaO₃ with Eu³⁺ to produce Eu³⁺-doped GaO₃.

18. The method according to claim 17 where coating the SiO₂ nanoparticles comprising coating with Eu³⁺-doped GaO₃, the method further comprising nitriding the Eu³⁺-doped GaO₃ to produce a Eu²⁺-doped GaN@SiO₂ nanocomposite that is a blue light emitting nanomaterial.

19. The method according to claim 18 further comprising coupling the blue light emitting nanomaterial to a photonic crystal.

20. The method according to claim 16 comprising growing In₂O₃ on the silica nanoparticles to form In₂O₃@SiO₂.

21. The method according to claim 20 further comprising nitriding the In₂O₃@SiO₂ to produce an InN@SiO₂ nanocomposite, thereby producing the blue light emitting nanomaterial.

22. The method of claim 21 wherein a blue light emitting interface emits blue light with a maximum at about 410 nm to about 450 nm.

23. The method of claim 12 wherein the blue light emitting interface emits blue light with a maximum at about 420 nm to about 430 nm.

24. The method of claim 16 further comprising coating the nanomaterial.

25. The method of claim 24 wherein coating comprises coating with a polymer.

26. The method of claim 15 wherein the polymer is polyalkyl acrylate.

27. The method according to claim 26 where the polyalkyl acrylate is polymethyl methacrylate.

28. The method according to claim 16 further comprising coupling the blue light emitting nanomaterial to a photonic crystal.

29. A blue light emitting nanomaterial produced according to claim 1.

30. A blue light emitting nanomaterial comprising Mg²⁺, Eu²⁺ or Zn²⁺ doped gallium or indium nitride.

31. The blue light emitting nanomaterial of claim 30 further characterized by the presence of Mg²⁺- or Zn²⁺-controlled defects.

32. The blue light emitting nanomaterial of claim 30 that emits blue light with a maximum at about 410 nm to about 450 nm.

33. The blue light emitting nanomaterial of claim 30 that emits blue light with a maximum at about 420 nm to about 430 nm.

34. The blue light emitting nanomaterial of claim 30 wherein the nanomaterial is a nanocrystal.

35. The blue light emitting nanomaterial of claim 30, wherein the nanomaterial is coated with an organic phosphine oxide.

36. The blue light emitting nanomaterial of claim 30, wherein the nanomaterial is coated with a trialkylphosphine oxide.

37. The blue light emitting nanomaterial of claim 36 where the trialkylphosphine oxide is trioctylphosphine oxide.

38. The blue light emitting nanomaterial of claim 30 coupled to a photonic crystal.

39. A blue light emitting nanocomposite comprising Eu²⁺-doped GaN@SiO₂ nanocomposites having an interface or InN@SiO₂ nanocomposites having an interface.

40. The blue light emitting nanocomposites of claim 39 that emit blue light with a maximum at about 410 nm to about 450 nm.

41. The blue light emitting nanocomposites of claim 39 that emit blue light with a maximum at about 420 nm to about 430 nm.

42. The blue light emitting nanocomposites of claim 39 wherein the nanocomposites are coated.

43. The blue light emitting nanocomposites of claim 42 coated with a polymer.

44. The blue light emitting nanocomposites of claim 43 wherein the polymer is polyalkyl acrylate.

45. The blue light emitting nanocomposites of claim 44 where the polyalkyl acrylate is polymethyl methacrylate.

46. A method for making an electroluminescence device that emits blue light, comprising:
forming a blue light emitting nanomaterial; and
incorporating the blue light emitting nanomaterial into an electroluminescence device.

47. The method according to claim 46 where forming a blue light emitting nanomaterial comprises:
nitriding Group 13 metals to produce nitrided Group 13 metals; and
doping the nitrided Group 13 metals with a dopant having a plus 2 charge, thereby forming a doped blue light emitting nanomaterial.

48. The method according to claim 47 where forming a blue light emitting nanomaterial comprises
preparing SiO₂ nanoparticles;
doping a Group 13 metal oxide with a dopant having a plus 2 charge, or a dopant that can be reduced to a plus 2 charged, to produce a doped nanomaterial;
coating the SiO₂ nanoparticles with the doped nanomaterial; and
nitriding the doped nanomaterial to produce a blue light emitting nanomaterial.

49. The method according to claim 48 where the nanomaterial is a polymer coated Eu²⁺-doped GaN/SiO₂ nanocomposites or InN@SiO₂.

50. The method according to claim 49 where the polymer PEDOT:PSS.

51. A nanocrystal-based electroluminescence device comprising an organic/inorganic structure selected from indium tin oxide/poly(3,4-ethylene dioxythiophene) doped with poly(styrenesulphonic acid) (PEDOT:PSS)/GaN:Mg nanocrystal/Ca/Al, indium tin oxide/poly(3,4-ethylene dioxythiophene) doped with poly(styrenesulphonic acid) (PEDOT:PSS)/Eu²⁺-doped GaN@SiO₂ nanocomposite/Ca//Al, indium tin oxide//InN@SiO₂ nanocomposite//Ca//Al, or combinations thereof.

52-53. (canceled)
